(19) United States
(12) Patent Application Publication
(10) Pub. No.: US 2016/0068957 A1
(43) Pub. Date: Mar. 10, 2016

(54) CORROSION RESISTANT METAL AND METAL ALLOY COATINGS CONTAINING SUPERSATURATED CONCENTRATIONS OF CORROSION INHIBITING ELEMENTS AND METHODS AND SYSTEMS FOR MAKING THE SAME

(71) Applicants: Haydn N.G. WADLEY, (US); Arthur H. HEUER, Cleveland Height, OH (US); Paul NATISHAN, Crofton, MD (US); UNIVERSITY OF VIRGINIA PATENT FOUNDATION, Charlottesville, VA (US)

(72) Inventors: Haydn N.G. Wadley, Keswick, VA (US); Arthur H. Heuer, Cleveland Heights, OH (US); Paul Natishan, Crofton, MD (US)

(21) Appl. No.: 14/783,993

(22) PCT Filed: Apr. 11, 2014
(86) PCT No.: PCT/US14/33821

§ 371 Date: Oct. 12, 2015

Related U.S. Application Data
(60) Provisional application No. 61/811,379, filed on Apr. 12, 2013.

(51) Int. Cl. C23C 16/455; C09D 5/08; C23C 16/513

(52) U.S. Cl. CPC C23C 16/45514; C23C 16/513; C09D 5/084

(57) ABSTRACT

A method and apparatus for producing a corrosion inhibiting coating for metal and metal alloy substrates. The coating is comprised of a metal or metal alloy that is similar in composition to the substrate to be coated, further combined with a corrosion inhibiting material. The corrosion inhibiting material may be a refractory metal or metalloid. The method and apparatus for producing the coating allows for the corrosion inhibiting coating to have a supersaturated concentration of the corrosion inhibiting material alloyed with another metal or metal alloy. The method and apparatus allow for the selective vaporization of material sources to make the coating vapor, which are then entrained in a high speed gas flow that directs the coating vapor onto the substrate. Optional plasma assistance and application of a voltage to the substrate may be used. The coating may be customized for a variety of applications.

### CROSS REFERENCE TO RELATED APPLICATIONS

The present application claims priority under 35 U.S.C. §119(e) from U.S. Provisional Application Ser. No. 61/811,379, filed Apr. 12, 2013, entitled “Corrosion Resistant Aluminum Alloy Coatings Containing Refractory Elements; and Methods and Systems for Making the Same;” the disclosure of which is hereby incorporated by reference herein in its entirety.

### STATEMENT OF GOVERNMENT INTEREST

The present invention was developed with United States Government Support under Office of Naval Research Grant No. N00173-11-1-G003. The government has certain rights in the invention.

### FIELD OF THE INVENTION

The present invention relates generally to the field of corrosion resistant coatings. More specifically, the invention relates to the subfield of metallic coatings containing supersaturated levels of alloying elements.

### BACKGROUND

Metal corrosion, particularly in salt water environments, poses a number of challenges for engineers and designers. Corrosion of metals reduces the service live of structures and devices, increases costs of maintenance and repair, leads to longer downtimes for equipment, and may pose safety risks due to malfunction or breakage of components. Improved protection of metals and metal alloys is an important area of research and development.

Certain methods of preventing corrosion in metal and metal alloy substrates include various coatings or paints and alloying to produce more corrosion resistant layers or compositions. However, there are a number of disadvantages in each approach. Many coatings may be easily chipped during use, exposing the substrate and leading to corrosion. In addition to impacts, traditional coatings or paints may crack from the flexure of the substrate material during use. This can lead to chipping or gaps in the protective layer, allowing corrosion despite the protective layer.

Alloying metals or metal alloys with corrosion inhibiting materials may also have certain disadvantages. When alloying the corrosion inhibiting material directly into the metal or metal alloy, a relatively large amount of that material is required compared to a surface coating because it is distributed throughout the volume of the substrate. Furthermore, much of that corrosion inhibition is wasted because it is located within the volume rather than on the surface where corrosion is most prevalent. It also may not be possible to apply supersaturated concentrations of refractory metals or metalloid corrosion inhibiting materials to bulk material components. Even if such concentrations were possible, the corrosion inhibiting material might adversely affect other material properties, such as tensile strength or strength to weight ratio. Finally, the addition of a refractory metal or metalloid may limit choice in what other materials may be used in a particular application, potentially disqualifying a material that may have other superior properties for considerations of corrosion resistance.

### OVERVIEW

An aspect of an embodiment of the present invention provides, among other things, the use of alloy coatings containing supersaturated concentrations of refractory metals and or metalloid elements (such as nitrogen) as corrosion inhibiting coatings applied to metals and metal alloys. An aspect of an embodiment of the present invention provides, among other things, the use of directed vapor deposition and other physical, chemical, electrochemical and electrophoretic methods and related systems for the application of such coatings. In particular, an aspect of an embodiment of the present invention provides the use of aluminum alloy coatings containing supersaturated concentrations of refractory metals and metalloid elements as corrosion inhibiting coatings applied to aluminum and aluminum alloys.

Aluminum alloys are increasingly used on ships and are ubiquitous in airframes. Aluminum alloys used in salt water environments are susceptible to localized pitting corrosion. While there are significant differences in the rates of corrosion between different alloy types, all are vulnerable to this mechanism of attack in marine environments. The phenomenon results from a local breakdown of the passive (protective) oxide film that naturally forms on aluminum alloy surfaces. Therefore a means of protecting these aluminum alloys is highly desirable to decrease maintenance, increase asset availability, and increase service life. An aspect of an embodiment of the present invention provides, among other things, corrosion inhibiting/preventive coatings and methods of application to protect aluminum alloys used in marine and other environments from localized corrosion. While several elements such as tungsten (W), niobium (Nb), chromium (Cr), molybdenum (Mo), tantalum (Ta), zirconium (Zr), nitrogen (N), boron (B), phosphorus (P), vanadium (V), and yttrium (Y) have been shown to be effective at mitigating pitting corrosion, none are sufficiently soluble that they can be added as alloying elements during conventional melt phase processing of aluminum alloys. Even if such approaches were developed (for example by rapid solidification processing), they would result in an inefficient use of these costly alloy elements since they are then distributed throughout the alloy interior where they serve no corrosion inhibiting function. Vapor phase processing using ion implantation of these elements or sputter deposition approaches that deposit them on a surface have shown promise for creating surface films that are enriched in the elements of interest. However, these processes are difficult and expensive to implement because of the high equipment cost, low throughput, and the need for high vacuum process environments. They are also line of sight deposition methods and therefore incapable of uniformly coating components of complex shape.

It should also be appreciated that a number of metals and metal alloys are also susceptible to corrosion, particularly in salt water or marine environments. Similar protective coatings are possible on substrates composed of copper, iron, nickel, and magnesium, among others, in either their pure or alloyed states. As is the case with aluminum, coatings containing tungsten, niobium, chromium, molybdenum, tantalum, zirconium, nitrogen, boron, phosphorus, vanadium and yttrium may mitigate or prevent corrosion from occurring.

An aspect of an embodiment of the present invention provides, among other things, a directed vapor deposition (DVD) coating process that overcomes many of these problems. Directed vapor deposition is an electron beam physical vapor deposition technique which utilizes a high-speed gas stream to entrain a thermally evaporated vapor flux and transport it to a substrate where it is deposited with a high material deposition efficiency. In the present inventors' novel DVD system, multi-source co-evaporation from individual source materials can be used to create controlled composition vapor plumes. It is also possible to perform reactive deposition if a gas, such as oxygen or nitrogen that reacts with the vapor atoms or molecules, is present in the chamber. The reaction rates with these gases can be greatly increased by creating a plasma near the region of deposition. One approach for this is to use a low voltage electron beam, such as that created by a hollow cathode, to ionize the working gas and evaporants. The combination of a low vacuum and the potentially high deposition rate often results in the deposition of porous coatings, especially for oblique angles of vapor incidence and at low deposition temperatures where the mobility of the vapor species on the substrate is low. Dense films can be synthesized at low temperatures using the plasma-assisted directed vapor deposition approach. This plasma assistance provides a non thermal mechanism for assembling a structure and in particular, provides the opportunity for creating highly metastable structures, including those with very high (supersaturated) solute concentrations. The DVD technique also enables non-line-of-sight deposition which can be utilized to coat cylindrical or irregularly shaped objects. Because vapor is deposited from the stream lines of the gas flow by binary scattering, a coating can be deposited on any surface that is reachable by the flowing carrier gas stream. As a result, quite complicated shapes can be coated including those with regions that were never in the line of sight of the vapor source. An important aspect, among others, of an embodiment of the present invention, is to create a coating of similar composition to the metal or metal alloy to be protected but with one or more of the protective elements added in significant concentration. Also note that this coating must make very good physical and chemical contact with the base alloy to avoid delamination. It is therefore necessary to use various methods such as sputter etching to remove thick oxide films that can form on metal or metal alloys prior to coating deposition. The use of the plasma assisted DVD technique or others including physical or chemical vapor deposition or electrochemical or electrophoretic deposition are envisaged as a means for the practical application of such coatings. The various available depositing methods are considered part of the present invention, and may be employed within the context of the invention.

It should be appreciated that the various embodiments of the present invention corrosion coatings may be deposited on metals or metallic alloys wherein corrosion resistance needs to be enhanced. For example, it could be used to increase the corrosion resistance of an automobile body panel by depositing the alloy or metal the panel is made from plus the additional element(s) that enhance corrosion resistance. It could be used to protect marine vessel hulls or decks in the same way, or parts for hovercraft, and other amphibious vehicles exposed to salt water. There would be many applications on aircraft, especially those operating in or near marine environments, which are major users of aluminum alloys. It could be used to coat other things too, such as window frames, door frames, parts of the chassis of an automobile, etc. Certain kinds of structures with high surface area might be particular areas of interest for application. For example, the surface of aluminum or other metallic honeycombs used in sandwich panels are vulnerable to corrosion, as are other cellular structures with high specific surface area. It should be appreciated that various embodiments of the cellular structures, or any structures for that matter, disclosed in the references that have been incorporated by reference in this disclosure may be provided as a substrate(s) herein.

Some examples of substrates may include, but not limited thereto, frames to any air, space, or water craft, vehicle or robot. Another example of substrates may be include, but not limited thereto, any outer skin or inner skin, as well as other components, of any air, space, or water craft, vehicle or robot.

Some examples of substrates may include, but not limited thereto, any building structures or components of building structures.

Some examples of substrates may include, but not limited thereto, any industrial or commercial systems and equipment or components of such systems and equipment.

Some examples of substrates may include, but not limited thereto, fasteners, brackets, hinges, decorative fixtures, or other components of machinery, equipment or items.

Some examples of substrates may include, but not limited thereto, any automotive component, bodies, frames, chassis and components. Similarly, this may extend any transportation land, air, or sea vehicle, craft or robot.

Some examples of substrates may include, but not limited thereto, any electronics systems or components of such electronic systems.

For example, but not limited thereto, it should be appreciated that the various embodiments of the present invention corrosion coatings may be deposited on aluminum or aluminum alloys wherein corrosion resistance needs to be enhanced.

Applicants show as examples the deposition of coatings consisting of a mixture of an aluminum 5083 alloy with either zirconium or tantalum added. These coatings have been subjected to pitting corrosion testing in salt water solutions with the pitting resistance found to be significantly increased. These preliminary experiments confirm that metastable alloy coatings that are highly enriched in refractory metals significantly increase the pitting corrosion resistance of alloys and that a DVD method can be used to successfully apply such coatings.

An aspect of an embodiment of the present invention provides, but not limited thereto, a method for protecting an aluminum substrate or an aluminum alloy substrate from corrosion. The method may comprise: at least partially enclosing a substrate to be coated in an enclosure; providing a first material source comprising aluminum or aluminum alloy; providing one or more corrosion inhibiting material sources of different composition as the substrate; providing an energy source for vaporizing the first material source and the one or more corrosion inhibiting material sources; vaporizing the first material source and the one or more corrosion inhibiting material sources with the energy source to create a coating vapor; providing a gas flow for mixing and carrying the coating vapor to the substrate; and coating the sample with an alloy of the first material source and a supersaturated concentration of at least one of the one or more corrosion inhibiting material sources.

An aspect of an embodiment of the present invention provides, but not limited thereto, an apparatus for protecting an aluminum substrate or an aluminum alloy substrate from corrosion. The apparatus may comprise: an enclosure; a crucible for holding at least two material sources; an energy source for vaporizing the at least two material sources; and a nozzle for directing a gas flow onto a sample resulting in a coating of a supersaturated alloy of at least one of the at least two material sources on the aluminum substrate or the aluminum alloy substrate.

An aspect of an embodiment of the present invention provides, but not limited thereto, a composition for coating an aluminum substrate or an aluminum alloy substrate to protect the substrate from corrosion. The coating of the substrate may comprise: aluminum or aluminum alloy and one or more corrosion inhibiting materials alloyed and deposited as a coating on the aluminum or aluminum alloy substrate; wherein the alloyed and deposited coating comprises aluminum or aluminum alloy and a supersaturated concentration of at least one of the one or more corrosion inhibiting material.

An aspect of an embodiment of the present invention provides, but not limited thereto, a method for protecting a metal substrate or a metal alloy substrate from corrosion. The method may comprise: at least partially enclosing a substrate to be coated in an enclosure; providing a first material source comprising metal or metal alloy; providing one or more corrosion inhibiting material sources of different composition as the substrate; providing an energy source for vaporizing the first material source and the one or more corrosion inhibiting material sources; vaporizing the first material source and the one or more corrosion inhibiting material sources with the energy source to create a coating vapor; providing a gas flow for mixing and carrying the coating vapor to the substrate; and coating the sample with an alloy of the first material source and a supersaturated concentration of at least one of the one or more corrosion inhibiting material sources.

An aspect of an embodiment of the present invention provides, but not limited thereto, an apparatus for protecting a metal substrate or a metal alloy substrate from corrosion. The apparatus may comprise: an enclosure; a crucible for holding at least two material sources; an energy source for vaporizing the at least two material sources; and a nozzle for directing a gas flow onto a sample resulting in a coating of a supersaturated alloy of at least one of the at least two material sources on the metal substrate or the metal alloy substrate.

An aspect of an embodiment of the present invention provides, but not limited thereto, a composition for coating a metal substrate or metal alloy substrate to protect the substrate from corrosion. The coating of the substrate comprises: metal or metal alloy and one or more corrosion inhibiting materials alloyed and deposited as a coating on the metal or metal alloy substrate; wherein the alloyed and deposited coating comprises metal or metal alloy and a supersaturated concentration level of at least one of the one or more corrosion inhibiting materials.

An aspect of an embodiment of the present invention provides, but not limited thereto, a method for removing oxidation or contamination from a substrate. The method may comprise: providing a substrate to be cleaned or etched; generating or providing a plasma source; applying a negative bias to the substrate; and bombarding the substrate with ions of the plasma.

An aspect of an embodiment of the present invention provides, but not limited thereto, a method for forming a synthetic oxide layer on a substrate. The method may comprise: providing a coated or uncoated substrate to be oxidized; generating or providing a plasma source composed of a material that may oxidize the coated or uncoated substrate; applying a negative bias to the substrate; and bombarding the substrate with the ions of the plasma.

An aspect of an embodiment of the present invention provides, but not limited thereto, a method and apparatus for producing a corrosion inhibiting coating for metal and metal alloy substrates. The coating is comprised of a metal or metal alloy that is similar in composition to the substrate to be coated, further combined with a corrosion inhibiting material. The corrosion inhibiting material may be a refractory metal or metalloid. The method and apparatus for producing the coating allows for the corrosion inhibiting coating to have a supersaturated concentration of the corrosion inhibiting material alloyed with another metal or metal alloy. The method and apparatus allow for the selective vaporization of material sources to make the coating vapor, which are then entrained in a high speed gas flow that directs the coating vapor onto the substrate. Optional plasma assistance and application of a voltage to the substrate may be used. The coating may be customized for a variety of applications.

### DESCRIPTION OF THE DRAWINGS

The accompanying drawings, which are incorporated into and form a part of the instant specification, illustrate several aspects and embodiments of the present invention and, together with the description herein, serve to explain the principles of the invention. The drawings are provided only for the purpose of illustrating select embodiments of the invention and are not to be construed as limiting the invention.

FIG. 1 provides a schematic illustration of an embodiment of the directed vapor deposition apparatus with plasma assist during operation.

FIG. 2 provides a graph of the electron energy distribution in a hollow cathode-produced plasma.

FIG. 3 provides a schematic illustration of an embodiment of the plasma generation apparatus.

FIG. 4 provides a photographic depiction of an embodiment of the plasma generation apparatus during operation.

FIG. 5 provides a micrographic depiction of an example of the corrosion resistant coating as applied to a substrate.

FIG. 6 provides an equilibrium phase diagram of an Al—Zr binary alloy system.

FIG. 7 provides a graph of anodic polarization curves for a Zr-5083 coating and uncoated 5083 aluminum in deaerated 0.6M NaCl.

FIG. 8 provides anodic polarization curves for tantalum coated and uncoated 5083 aluminum in deaerated 0.6M NaCl.

### DETAILED DESCRIPTION OF EXEMPLARY EMBODIMENTS OF THE INVENTION

Metals and metal alloys used in salt water environments are susceptible to corrosion. While there are significant differences in the rates of corrosion between different metals and metal alloy types, all may be vulnerable to this mechanism of attack in aqueous environments. The phenomenon results from a local breakdown in the effectiveness of the oxide (passivating) film that naturally forms on atmospherically exposed metal and metal alloy surfaces. This native oxide film breakdown can occur at intermetallic particles which are present in all engineering alloys. This film breakdown exposes bare metal or alloy to local electrochemical attack and results in corrosion. The mechanism of oxide breakdown begins with the adsorption of Cl⁻ ions on the surface, which is controlled by the surface charge state of the oxide. If the net charge is positive, Cl⁻ ions are attracted to the surface and corrosion can occur. The surface charge state is dependent upon many characteristics of the oxide, including its composition, state of hydration, conductivity, bonding environments, etc. The control of these quantities provides a potential route for controlling pitting and corrosion.

Aluminum and its alloys are particularly susceptible to this mechanism for corrosion in salt water environments. In particular, aluminum and its alloys suffer from localized pitting due to breakdown of the native oxide layer from the adsorption of Cl⁻ ions.

An aspect of an embodiment of the present invention provides, among other things, a corrosion inhibiting coating for a metal or metal alloy substrate including a metal or metal alloy further alloyed with one or more refractory metals or metalloids.

While several elements (W, Nb, Cr, Mo, Ta, Zr, N, B, P, V, Y, etc., or the like) have been shown to be effective at mitigating corrosion and pitting, none are sufficiently soluble that they can be added as alloying elements during conventional melt phase processing of many engineering alloys. Even if such approaches were developed, for example by rapid solidification processing, they would result in an inefficient use of these costly alloying elements since they are then distributed throughout the alloy interior where they serve no corrosion inhibiting function. Vapor phase processing using ion implantation or sputter deposition approaches have shown promise for creating surface films that are enriched in the elements of interest. However, these fabrication processes are difficult and expensive to implement because of high equipment cost, low throughput, and the need for high-vacuum process environments. They are also incapable of uniformly coating components of a complex shape, particularly where some areas of the part to be coated are not in the line of sight of the vapor source.

An aspect of an embodiment of the present invention teaches a coating and process for making the same that overcomes many of these problems. It uses thermal techniques, for example intense electron beams, to vaporize one or more closely spaced source materials. These can be elemental metals or alloy sources provided that the source materials have similar vapor pressures at the temperature used for evaporation. The vapor plumes from the multiple sources are then entrained in a high-speed helium or other gas flow and directed to a substrate where deposition occurs. By choosing appropriate process conditions, it is possible to completely mix the multiple material source vapor plumes creating a homogeneous alloy plume. Plasmas can also be created within the process chamber providing opportunities to athermally control the surface assembly processes during low temperature film growth. This then enables the film to be supersaturated in elements that are normally of low solubility without segregation or intermetallic phase formation. Because vapor is deposited from the stream lines of the gas flow by binary scattering, a coating may be deposited on any surface that is reachable by the flowing carrier gas stream. As a result, complicated shapes and contours can be coated including those with regions that are not in the line of sight of the vapor. It should be appreciated that the various coating techniques of the present invention include line of sight, non line of sight, or a combination thereof.

An aspect of an embodiment of the present invention provides, among other things, the use of these coatings deposited upon the surface of metals or metal alloys for protecting them from corrosion. The films are made by co-evaporating (or co-sputtering or otherwise creating a vapor phase of) a metal or metal alloy of similar or identical composition to the metal or metal alloy to be protected and one or more pitting or corrosion mitigating elements (such as, but not limited, to W, Nb, Cr, Mo, Ta, Zr, N, B, P, V, Y, etc., or the like) and co-depositing them. The use of a reactive plasma assisted deposition approach may also be used to incorporate nitrogen or other materials into some of the alloy coatings. In each system, dense films with high concentrations of the corrosion mitigating elements, sometimes retained in supersaturated solid solution, provide significant corrosion protection. Supersaturated solutions are often defined as a chemical solution that is more highly concentrated than is normally possible under given conditions of temperature and pressure. Furthermore, to supersaturate a solution is to cause a chemical solution to be more highly concentrated than is normally possible under given conditions of temperature and pressure. Supersaturated solutions may refer to any state of matter, and in particular may be directed towards liquid solutions, liquid-solid solutions, and solid solutions.

Also claimed is the use of a plasma etching method to remove the native oxide on a substrate prior to the start of the deposition and the use of controlled plasma oxidation to create a synthetic oxide layer on the films after deposition. It should be appreciated that the coating technique disclosed herein may be a separate process from the etching technique.

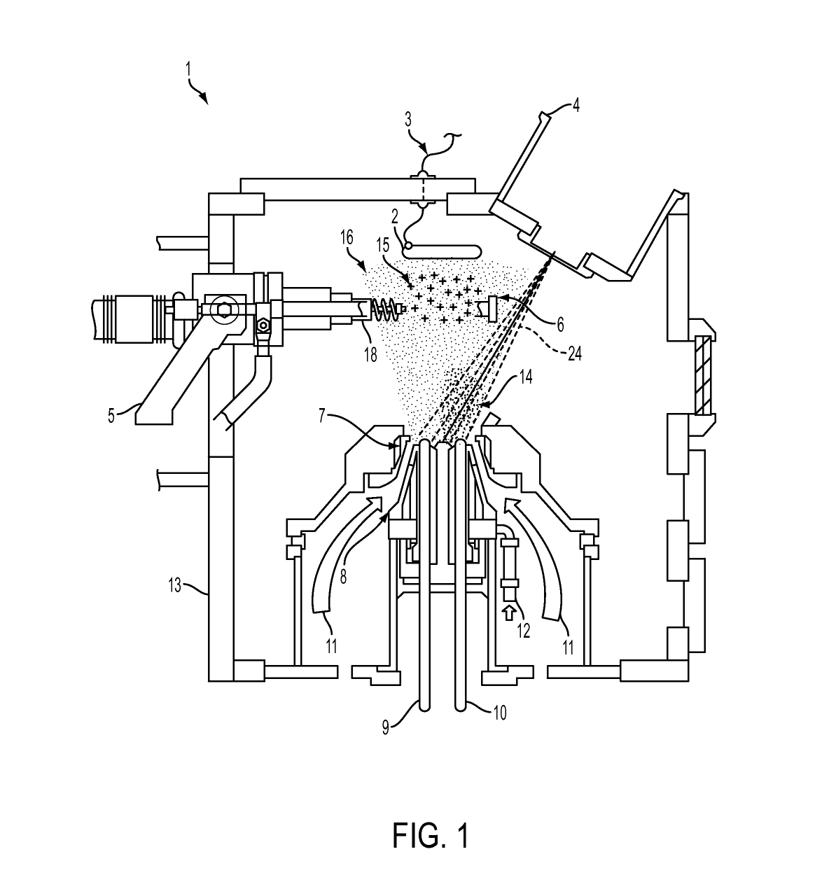

FIG. 1 provides a schematic illustration of an aspect of an embodiment of the Directed Vapor Deposition (DVD) system 1, for example, that may be used to produce coatings with supersaturated levels of corrosion inhibiting materials on a substrate 2. It should be appreciated that various available depositing methods or apparatuses are considered part of the present invention, and may be employed within the context of the invention. The DVD system includes an electron beam gun 4 with a maximum power of 10 kW and a beam accelerating voltage of 70 kV. It should be appreciated that in additional embodiments of the DVD system, different levels of maximum or minimum power and accelerating voltage may be desired or required for different types of substrate, material sources, or coating compositions. Furthermore, it should be appreciated that energy sources other than electron beam guns may be used, including but not limited to lasers, ion discharge guns, radiant heat sources, or direct heating. The high voltage is used to reduce the electron scattering cross-section from background gas atoms, permitting focused penetration of the beam over considerable distances in a low vacuum (high pressure) vapor deposition chamber. By impinging the electron beam 24 on first and second material sources 9, 10 (even if those materials have a very high melting point), the sources may be thermally vaporized into a coating vapor 14 by heating their surfaces into the liquid phase. The rate of vaporization depends upon the vapor pressure-temperature relation of the first and second material sources 9, 10. The vapor pressure rises very rapidly with surface temperature, and since this is controlled by the power of electron beams 24 impinging on the first and second material sources 9, 10, the electron beam power (or dwell time) incident upon the first and second material sources 9, 10 is used to control the coating vapor 14 emission rate and composition. The upper limit on the rate of evaporation may be very high, corresponding to deposition rates of hundreds of micrometers per second.

Normally, the creation of such a high coating vapor 14 concentration leads to nanoparticle formation and “sooty” deposits. However, the coating vapor 14 created in the DVD process is entrained in a high speed gas flow 11 and rapidly swept from the first and second material sources 9, 10 and diluted. This flow 11 is created by the expansion of a gas, such as helium, through a nozzle 7 located near the first and second material sources 9, 10. Crucibles 8 have been developed to co-evaporate multiple source materials 9, 10 with a single electron beam 24. In this case, the electron beam 24 scan pattern is programmed to rapidly jump the electron beam 24 between the first and second material sources 9, 10. Each individual source material may be evaporated with different rates by controlling the dwell time of electron beam 24 on each molten source pool. The ability to evaporate each individual source material with an independently controllable rate enables the deposition of a coating with a precise composition to be synthesized. High-speed beam scanning with a frequency of 100 kHz has been incorporated in the electron beam gun 4 to control the source melting precisely, thereby facilitating very high rates of evaporation. It should also be appreciated that electron beam 4 may use any rate of cycling, dwell time, or combinations thereof, as required to control the coating vapor 14 composition. If needed, multilayer deposition can be easily achieved by moving the electron beam 24 between the various source materials more slowly (without breaking the vacuum). It should be appreciated that electron beam 24 may be alternated between first and second material sources 9, 10, or any number of material sources in crucible 8, to create the appropriate composition of coating vapor 14 as desired or required by the user. As an example, crucible 8 may be configured to hold two, three or more different material sources, or multiples of the same source. Crucible 8 may also be configured in an annular or ring shape to allow gas flow 11 to move through its center.

It should be appreciated that FIG. 1 shows only one exemplary embodiment of the present invention and is not intended to limit other potential embodiments that may be desired or required. Notably, there are a number of variations that may be useful for particular applications. For instance, gas flow 11 may be composed of a number of gasses with different properties. Inert gasses, for example, but not limited to, helium, may be used for coatings where it is not desired to have a gas stream that is reactive with the coating vapor 14. Alternatively, a reactive gas, such as, but not limited to, nitrogen, may be used when it is desirable for the gas flow 11 to provide a chemical constituent to the coating. Furthermore, gas flows 11 may constitute a mixture of gasses, all of which are inert or reactive, or a combination of inert and reactive. It should also be appreciated that gas flow 11 may be provided at a number of different flow rates or speeds. For example, gas flow 11 may be supersonic, with speeds in the range of Mach 1-2.

Still referring to FIG. 1, it should be appreciated that nozzle 7 may be provided in a number of forms or configurations as desired or required. As shown in FIG. 1, nozzle 7 may be annular in shape and located around crucible 8. However, nozzle 7 may also be provided as a nozzle concentric to crucible 8 and first and second material sources 9, 10. Furthermore, it should be appreciated that nozzle 7 may be configured in any way within enclosure 13 such that it provides for adequate transportation and mixing of coating vapor 14. As such, nozzle 7 may be disposed above, below, or to the side of crucible 8 and first and second material sources 9, 10. It should also be appreciated that multiple nozzles may be used to provide gas flow 11 within enclosure 13. Furthermore, nozzle 7 may be located in such a way as to produce gas flow 11 such that the gas flow 11 is concentric to the material sources that are vaporized by electron beam 24.

Still referring to FIG. 1, it should be appreciated that crucible 8 may take any number of forms. Notably, in an aspect of an embodiment of the present invention, crucible 8 may be configured to accept coolant supply 12. Furthermore, in another aspect of an embodiment of the present invention, crucible 8 may be configured to accept any number of material sources as are desired or required to provide coating vapor 14 with 2, 3, or more constituent materials.

Still referring to FIG. 1, in an aspect of an embodiment of the present invention, an optional plasma assist system may be incorporated into the coating deposition apparatus 1. A plasma activation unit 5 in communication with a hollow cathode 18 works in conjunction with an anode 6 disposed across the enclosure 13. A gas, or combination of gasses, which may be inert, reactive, and of similar or different composition to the gas flow 11, flows through the plasma activation unit 5 and is ionized to create a plasma 15 within the enclosure 13. The plasma 15 mixes with the coating vapor 14 and gas flow 11 to create the mixed vapors and plasma 16. It should be appreciated that a user may alter the relative concentrations, pressures, and compositions of the plasma 15, gas flow 11, and coating vapor 14 to create mixed vapors and plasma 16 specifically suited to the substrate material, material sources, and the desired properties of the corrosion resistant alloy layer. It should also be appreciated that there is no requirement that the plasma 15 must be present for the proper functioning of all embodiments of the present invention. In such cases as the plasma 15 is not required, then the coating vapor 14 and gas flow 11 will combine to form mixed vapors 16 alone.

Still referring to FIG. 1, in an aspect of an embodiment of the present invention, a substrate bias 3 may be applied to the substrate 2 to aid in depositing the corrosion resistant coating on the substrate 2. Application of a substrate bias 3 may also be useful for other functions, including removal of a native oxide layer that may build up on substrate 2 and cause difficulty coating the substrate 2. It should be appreciated that the substrate bias 3 may be positive, negative, or alternating in polarity, and it may take on any value as desired or required by the user, including different values of voltage, amperage, or cycle time for alternating polarity.

During the deposition process, the upstream of the nozzle pressure (Pᵤ) is kept higher than the downstream pressure (or chamber pressure Pₒ). If the ratio of the pressure exceeds 2, a supersonic gas flow is created around the material source rod. The vapor atoms from the source material will then be entrained in the supersonic carrier gas flow, and rapidly transported (at 500-1000 m/s) to the substrate. The gas flow speed and density can be controlled by the choice of upstream pressure (Pᵤ) and downstream pressure (chamber pressure, Pₒ) ratio and the nozzle dimensions. The speed of a supersonic gas flow, U, can be estimated from the following equations:

U=M\sqrt{γRₛT} (1)

Where

γ=Ratio of specific heats (5/3 for helium),

M=Flow's Mach number, T=Absolute temperature (K), and

Rₛ=Specific gas constant (2077 J/kg/K for helium).

The Mach number is determined by a pressure ratio (Pᵤ/Pₒ):

$$\frac{{P}_{u}}{{P}_{o}} = {[ 1 + \frac{γ - 1}{2} {M}^{2} ]}^{γ / ( γ - 1 )} \qquad ( 2 )$$

These two equations indicate that the speed of a supersonic gas flow may be increased by increasing the pressure ratio (Pᵤ/Pₒ). If a reactive gas (oxygen or nitrogen) is mixed with helium and expanded into the chamber, the pressure difference rises and therefore the gas speed increases. Pressure ratios of 6 to 8 were used for the examples given.

The use of a supersonic gas flow promotes both a deposition rate and efficient utilization of the coating vapor by focusing the vapor flux plume to the dimensions of a substrate. This occurs because the coating vapor is transported along the gas flow streamlines. Binary scattering from these streamlines then leads to deposition onto substrates within one to two mean free scattering distances of the streamline. Since the scattering rate and distances are controlled by the local pressure and cross sections of the scattering species, it is possible to control the rate of vapor deposition by varying the gas pressure and flow velocity. Since streamlines may flow around corners, it is also possible to deposit vapor evenly onto complicated shapes, which is impossible using other physical vapor deposition processes. Because the DVD process is somewhat analogous to spray deposition, very large areas may be coated by directing the gas flow by swiveling the gas flows or nozzles, or by applying pressure gradients across the annular nozzle to aerodynamically vector the jet. It should also be appreciated that it in another aspect of an embodiment of the present invention, large areas may be covered by translating the substrate relative to the gas flow, or rotating the substrate relative to the gas flow, or translating and rotating the substrate relative to the gas flow or vice versa.

For the examples given, a two source crucible with 12.5 mm diameter material sources was used. One of the sources consisted of the aluminum alloy to be deposited (AA 5083). The second source consisted of either 5N purity Zr, Ta, W or Mo. A series of experiments were performed to establish the relationship between electron beam impingement conditions and the evaporation rate of each material, which was used this to establish a co-evaporation condition that created the desired vapor composition. It should be appreciated that this and other examples do not limit the materials, parameters, or results that are possible with the DVD process for producing supersaturated coatings.

When the DVD approach is conducted under a low-vacuum environment (7.5×10⁻³−0.75 Torr), coating vapor atoms are strongly thermalized and the DVD deposited coating may form porous columnar structures. However, under certain circumstances a less porous coating may be desired, so a plasma assisted deposition method may be used to deposit the coatings, as in the given examples. The combination of the high-rate evaporation process with a high-density plasma activation technique based upon hollow cathode arc discharge is useful for creating less-porous coatings. An optional hollow cathode-activated deposition (HAD) process may provide this functionality. The HAD process has been successfully used in the past for the deposition of dense films at low temperatures. However, the use of a plasma assist may create other concerns for the DVD coating process, and additional considerations in the parameters of the coating process may be necessary. For instance, plasma may defocus the coating vapor plume and shift the location of the plume's impingement with the substrate. Nevertheless, it provides at least one method for determine the viability of this general approach to achieve coatings with very high refractory (low solubility) element concentrations in solution. It should be appreciated that other means for plasma assist may be used which would be compatible with the DVD process for coating a substrate.

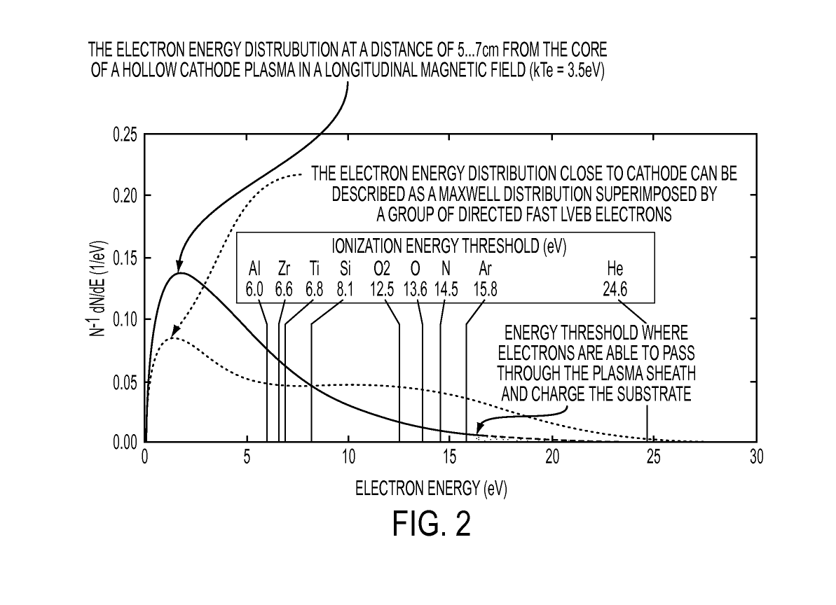

FIG. 2 provides a graph of the electron energy distribution in a hollow cathode-produced plasma (HCP). The dotted line represents the electron energy distribution function close to the cathode. The solid line represents the electron energy distribution at a distance of 5-7 cm from the core of the hollow cathode plasma in a longitudinal magnetic field. The hollow cathode arc discharge creates a very high electron density (˜10¹² cm⁻³). The high electron density of the hollow cathode plasma can be explained by the electron energy distribution function (EEDF), which consists of a Maxwellian distribution of the isotropic electrons and a superimposed group of directed electrons. Directed electrons comprise the low-voltage electron beam (LVEB) ranging from 0-25 eV and are accelerated at the exit of the cathode by a nearby anode (made of copper for these examples). Because the LVEB electrons have high energy, the ionization processes will take place in the core region of the discharge and the ions propagate by diffusion. By using the hollow cathode arc discharge, vapor ionization fractions of approximately 30% or more can be achieved. If an insulated (floating) substrate is placed near the plasma, then the ion current becomes the same as the electron current on the substrate. The floating potential (V_{f}) can be estimated from the relation:

$${V}_{f} = \frac{{kT}_{e}}{2 e} ln ( \frac{π}{2} \frac{{m}_{e}}{{M}_{i}} ) \qquad ( 3 )$$

where

k=Boltsmann constant (8.617×10⁻⁵ eV/K),

Tₑ=Electron temperature (K),

mₑ=Electron mass (9.11×10⁻³¹ kg), and

Mᵢ=Ion mass (for example, argon: 6.671×10⁻²⁶ kg).

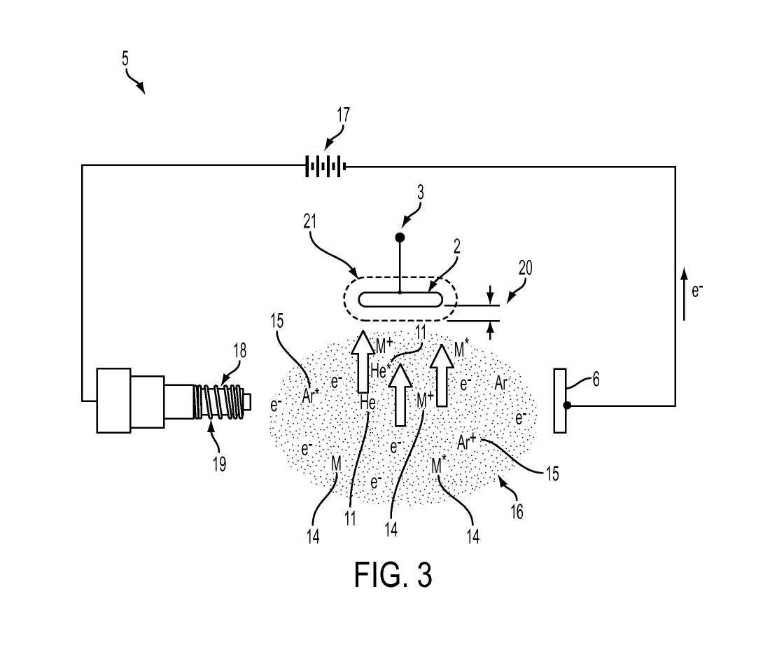

FIG. 3 provides a schematic illustration of an aspect of an embodiment of the plasma activation unit 5. The plasma activation unit 5 creates a plasma with a working gas, in this case the inert gas argon, which is used to assist in the directed vapor deposition technique to produce supersaturated alloy coatings. It should be appreciated that the plasma activation unit may take a variety of different shapes as desired or required, and that it may function with a number of different gasses, whether they are inert, reactive, or a combination thereof. The plasma activation unit 5 includes the hollow cathode 18, which is in communication with a heating element 19, which may be, but is not limited to, a tungsten coil. The hollow cathode 18 is disposed across from an anode 6. The hollow cathode 18 and anode 6 are in communication with a power supply 17 that provides energy for the creation of a plasma 15. The plasma 15 mixes with the gas flow 11 and coating vapors 14 created by the vaporization of a material source (not shown) to create a mixed vapor and plasma 16. The gas flow 11 with entrained coating vapor 14 flows generally upward and through plasma 15 to make mixed vapor and plasma 16, which flows generally towards and around the substrate 2 as shown by the arrows. It should be appreciated that the cathode of the plasma activation unit 5 may take many forms, and is not necessarily limited to a hollow cathode design. Furthermore, the plasma 15 is depicted as argon for illustrative purposes. However, it should not be construed as to limit the invention to argon, as any number of gasses, reactive or inert, may be suitable as a plasma source.

Still referring to FIG. 3, it should be appreciated that the hollow cathode 18 uses thermionic electron emission to create a low-voltage electron beam in the 0-25 eV range. These electrons are injected with a gas flow into the enclosure through the end orifice of the hollow cathode 18 toward the anode 6. A plasma consisting of electronically excited, ionized evaporants and working gas atoms/molecules is formed. If a negative potential 3 is applied to the substrate 2, a plasma sheath 21 is formed near the biased substrate 2 and this sets up a plasma sheath potential 20, which draws the ion flux toward the deposition surface.

Still referring to FIG. 3, a substrate bias 3 may be applied to a substrate 2 to assist in creating a supersaturated alloy coating. If a negative potential 3 is applied to a substrate 2, then it attracts positive ions and creates a plasma sheath 21 near the substrate 2. Because the plasma sheath 21 generates a sheath potential (Vₚₛ) 20 between the substrate 2 and the plasma 15 itself, the sheath potential 20 strongly accelerates positively ionized vapor atoms towards the substrate 2. This can increase the kinetic energy of the mixed vapor 16 from 0.2 eV to about 6.0 eV, enabling the formation of a dense coating without resorting to sufficient thermal activation to cause solute atom clustering or precipitation, create a vapor incidence angle more perpendicular to a film surface (less likely to form porosity), and increase the reaction rate between vapor atoms and reactive gases. Note that M designates coating vapor molecules 14, M* designates excited coating vapor molecules 14, and M⁺ designates ionized coating vapor molecules 14.

In an aspect of an embodiment of the present invention, a HCP current of 60 A was maintained with an external power supply. Argon with a flow rate of 0.3 slm was used as the hollow cathode working gas, and the emitted electrons from a heated hollow cathode therefore created an argon plasma. In the plasma assisted directed vapor deposition (PA-DVD) approach, since vapor atoms entrapped by a supersonic He gas jet are carried through the argon plasma, emitted electrons and argon ions are able to ionize some of vapor atoms and He gas while simultaneously transferring higher thermal energy.

Even though the HCP technique creates a dense argon plasma environment, LVEB electrons are still thermalized, which prevents the generation of a sufficient floating potential near the substrate. Previously, ion plating during the deposition process was used to modify film properties, such as film density, film adhesion, and film composition. If a substrate bias is applied, then the ion current (jᵢ) incident on the substrate can be modified as indicated by the relation:

$${j}_{i} = \frac{4}{9} {{ɛ}_{0} ( \frac{2 e}{{M}_{i}} )}^{\frac{1}{2}} \frac{{( {V}_{p} - {V}_{sb} )}^{\frac{3}{2}}}{{d}_{S}^{ 2}} \qquad ( 4 )$$

where

Mᵢ=Ion mass (for example, argon: 6.671×10⁻²⁶ kg),

Vₚ=Plasma potential (V),

V_{sb}=Substrate bias potential (V),

∈ₒ=Dielectric constant (8.84×10−14 F/cm), and

dₛ=Plasma sheath (mm).

Equation (4) indicates that if a negative bias is applied to a substrate, the ion current incident upon the substrate will increase. The increased current causes more ion bombardments of the growing film surface, which can enable further manipulation of the surface morphology and composition. As negative substrate bias increases, film structures may be modified from porous columnar to dense structures. However, the negative substrate bias results in energetic ion bombardments, which may increase the film stress and reduce the deposition rate (by resputtering). Furthermore, since the more energetic ion bombardments also deposit more heat in the substrate, they can enhance the atomic diffusional energy and precipitation reactions.

In an aspect of an embodiment of the PA-DVD approach described herein, a substrate bias technique is employed which can provide either a constant potential or an alternating bias of ±200 V. After a series of experimental trials it was found that a potential of −50V provided the best results. However, it should be appreciated that a number of different values for the bias may be used as desired or required in order to meet the specific requirements of a particular substrate, desired coating, or application. For example, the bias may be, positive, negative, or alternating polarity with differing values of voltage, current, and cycle time.

Another benefit of the substrate bias technique is that it may be used for surface cleaning and pre-treatment prior to deposition of a supersaturated coating. For some metals or metal alloys, a very thin (native) oxide layer is easily formed when exposed to air. This oxide layer is likely to affect the adhesion between the substrate and the coating. Ion bombardment of the oxide using a plasma and a negative substrate bias provides an effective way to clean the surface and remove much of the oxide layer, though some is always present due to the presence of a low oxygen and water vapor partial pressure in the deposition chamber. In an aspect of an embodiment of the present invention an argon plasma and a bias potential of −50V may be used to clean the surface of the substrate prior to the start of deposition. The ion etching treatment may be performed for about 10 minutes while the rest of the process parameters were adjusted prior to the start of deposition. It should be appreciated, though, that differing values for the bias potential, positive, negative, and/or alternating, and different amounts of time may be used for effective ion etching treatment based on the material and the extent of the oxide layer formation. It should also be appreciated that a synthetic oxide layer may be formed on the coated substrate or uncoated substrate by ion barbardment with a reactive or oxidizing plasma, for example.

A series of coating trials are given to identify conditions that enable directed vapor deposition of refractory metal-doped coatings of an aluminum alloy 5083 on 25 mm by 25 mm by 6.4 mm thick pre-cleaned plates of aluminum alloy 5083. AA5083 source rods with the diameter of 12.5 mm were obtained. High purity refractory metals (Zr, Ta, W and Mo) were also obtained. The substrates were polished to 1 μm with diamond suspension. The coatings were typically deposited at a pressure of 11-12 Pa.

As an example of an embodiment of the present invention, a refractory metal and AA5083 rod were placed in a dual crucible. In order to co-evaporate two source rods with a single electron beam, the electron beam scan pattern was programmed to rapidly jump the electron beam between the two sources. Each individual source material could be evaporated at different rates by controlling the dwell time of the electron beam on each molten source pool. The source materials were continuously raised during evaporation to compensate for their evaporation.

When a hollow cathode plasma was activated, the emitted electrons moved from the hollow cathode to the copper anode and then flowed into the current meter of the external power supply. In this way, the hollow cathode system forms a closed circuit during the PA-DVD deposition process. The plasma current was controlled by an external power supply and measured by a current meter in the external power supply. Table 1 shows the deposition conditions used for growth of refractory metal doped films.

TABLE 1
Deposition conditions of metal doped AA5083 films. The pressure ratio is a ratio
of the upstream pressure (Pu) to the downstream pressure (chamber pressure, Po).

| | | | | | | | Composition |
|---|---|---|---|---|---|---|---|
| | Plasma | Beam | | | Feeding | Deposition | of Doped |
| Source | Current | Current | He/Ar | Pressure | Rate | Time | Element |
| Rods | (A) | (mA) | (slm) | Ratio | (mm/min) | (mins) | (at. %) |
| AA5083/Zr | 60 | 42/17-18 | 8.0/0.3 | 6.1 | 0.2/0.05-0.1 | 60 | 10-20% |
| AA5083/Ta | | 42/25-30 | | 7.1 | 0.2/0.01 | 60 | 10-95% |

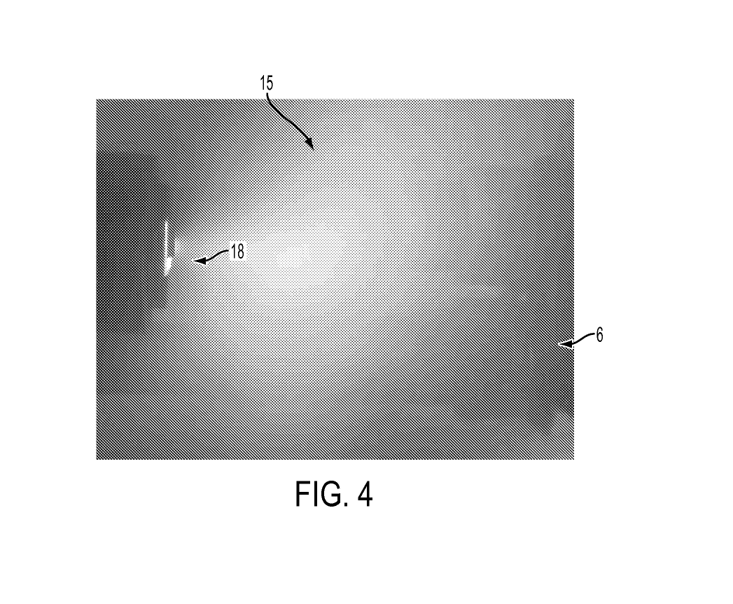

FIG. 4 provides a photographic depiction of an embodiment of the plasma generation apparatus during operation. A hollow cathode 18 was energized in association with an anode 6. As a result of the energized hollow cathode 18 and anode 6 in the presence of a gas flowing through the hollow cathode 18, plasma 15 was created. The plasma propagated vertically upwards in this figure. Optionally the hollow cathode 18 may be heated with a heating element or other heat source, such as a tungsten coil. This can result in thermionic electron emission, generating thermal electrons, which create a low-voltage electron beam ranging from 3 eV to 25 eV. When the low-voltage electron beam is generated, gas may be introduced into the chamber through the hollow cathode 18 and become ionized.

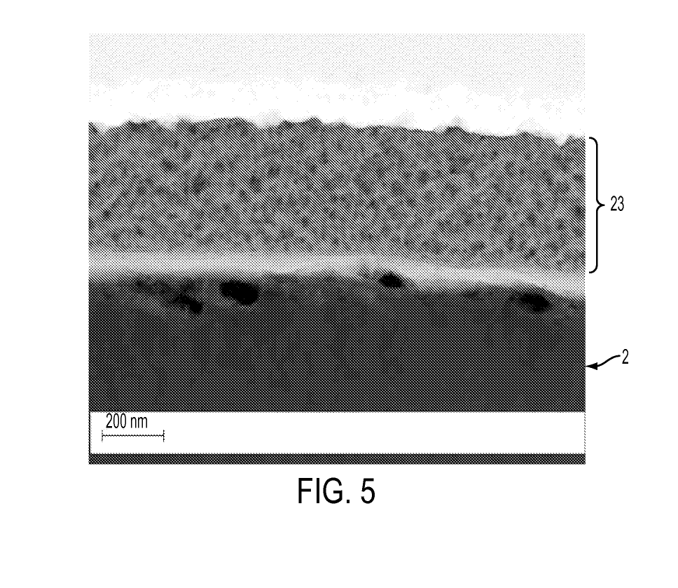

FIG. 5 provides a micrographic depiction of an aspect of an embodiment of the present invention. The corrosion resistant alloy layer 23 is applied to a substrate 2. It should be appreciated that the corrosion resistant alloy layer 23 contains a supersaturated concentration of a refractory metal or metalloid that assists in the prevention of corrosion of the substrate 2. In the micrographic depiction given, the corrosion resistant alloy layer 23 is a supersaturated composition of aluminum 5083 alloy enriched with 20% zirconium deposited on an aluminum 5083 alloy substrate 2. The figure also includes an interface region. However, it should be appreciated that the present invention is not limited to this particular composition or embodiment. Rather, it should be appreciated that the substrate may be composed of any metal or metal alloy. In particular, aluminum, copper, magnesium, iron, or nickel, either as pure metal or in alloyed form, may constitute the substrate 2. Furthermore, the corrosion resistant alloy layer 23 may be composed of any metal or metal alloy, including, but not limited to, aluminum, copper, magnesium, iron, or nickel, either as pure metal or in alloyed form, deposited with a supersaturated concentration of one or more corrosion resisting materials, wherein one of the one or more corrosion resistant materials may be at a supersaturated concentration individually, the combination of the one or more corrosion resistant materials is supersaturated in combination, or wherein all of the corrosion resistant materials are individually present in a supersaturated concentration. Corrosion resistant materials include, but are not limited to, refractory metals or metalloids. In particular, though not an exhaustive list and in no way limiting, tungsten, niobium, chromium, molybdenum, tantalum, zirconium, nitrogen, boron, phosphorus, vanadium, and yttrium may be used as the corrosion resistant constituent of the corrosion resistant alloy layer 23.

Still referring to FIG. 5, it should be appreciated that the thickness of the corrosion resistant alloy layer 23 may vary as desired or required by the user. For instance, coating thickness may be in the range of 400 nm, though it may also be thicker or thinner. Corrosion resistant alloy layer 23 thickness may, in an aspect of an embodiment of the present invention, be considered as a thin film, which may be defined as a layer that depends on the substrate 2 for rigidity. However, it should be appreciated that any thickness of corrosion resistant alloy layer 23 as required for the particular application regarding properties of cost, ease of manufacture, resilience, toughness, durability, substrate shape, contours or surface area, or service life may be used.

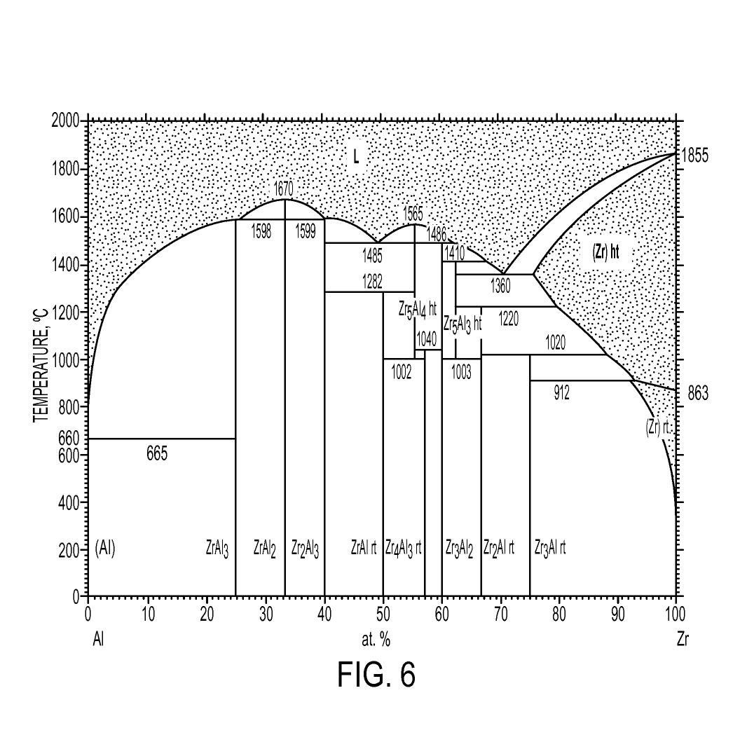

As an example of an aspect of an embodiment of the present invention, an Al 5083 alloy coating enriched with 20% Zr was applied to a substrate. This composition was selected following a series of trial experiments, which began by establishing the base pressure achievable with the pumping system. Before coating deposition was conducted, the initial enclosure vacuum pressure was approximately 0.1 Pa. The mixture of 8 standard liter/min (slm) He carrier gas flow and 0.3 slm Ar plasma flow was used during the deposition. The coatings were found to contain a metastable Al₃Zr phase. See the Al—Zr equilibrium phase diagram of FIG. 6.

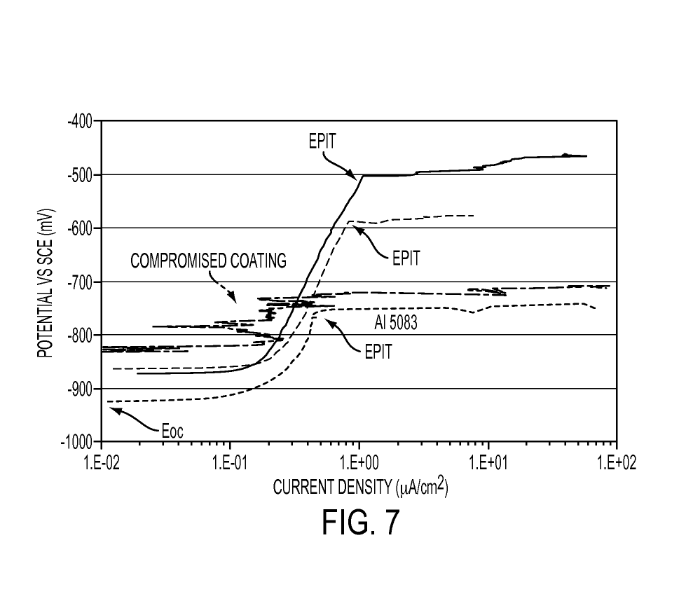

FIG. 7 provides a graphical depiction of anodic polarization curves that show the open circuit potential (Eoc) and pitting potential (Epit) for a Zr-5083 coating. Epit occurs at approximately −500 mV in this figure. Epit is the potential where there is an abrupt increase in current density compared to the passive region where the current density increase with potential is very small. Referring to the figure, Epit is designated for the base alloy (Al 5083) as well as the other coatings. The Epit value for the compromised coating is essentially that of the base alloy. Eoc is the potential of the sample without an applied potential. It is marked by the beginning point on the polarization curve in these scans. In this example, there was some variability of coating composition across the surface. The average Eoc value was −856 mV with a range between −869 mV and −873 mV and the average Epit was −553 mV with a range between −509 mV and −597 mV. The increase in Epit compared to the uncoated Al 5083 was 209 mV. This result shows the ability of DVD to produce a supersaturated coating with a higher Epit value than the base metal substrate.

Still referring to FIG. 7, a polarization curve for a region where the supersaturated coating was compromised is provided. The large current excursions and the Epit value, −763 mV, which is essentially the same as the average Epit of uncoated Al 5083, −762 mV, are indicative of a delaminated or cracked coating. This demonstrates the importance of using process conditions that avoid compromise of the coating.

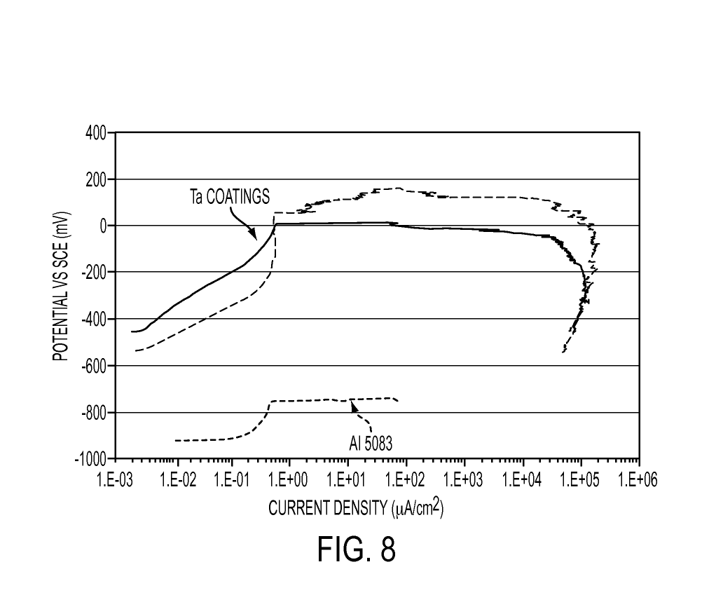

FIG. 8 provides a graphical depiction of anodic polarization curves that show Eoc and Epit values for supersaturated tantalum coatings and an untreated Al 5083 sample for comparison. The average of the Eoc value was −500 mV with a range between −541 mV and −459 mV and the average Epit was +24 mV with a range between +8 mV and +35 mV. The increase in Epit compared to the uncoated Al 5083 was 786 mV.

In another aspect of an embodiment of the present invention, nitrogen doped AA5083 deposition may be performed by adding nitrogen (N₂) to a helium gas flow. Since the neutral vapor atoms are entrapped and carried through the argon plasma by the supersonic He+N₂ gas flow, emitted electrons and argon ions are able to ionize some coating vapor atoms and He+N₂ gas while simultaneously transferring higher thermal energy. The low-vacuum environment of the plasma assist-DVD system provides a high collision rate between coating vapor atoms and nitrogen, which increases the reaction rate.

An aspect of various embodiments of the present invention may provide a number of novel and nonobvious features, elements and characteristics, such as but not limited thereto, the following:
A coating that protects metal and metal alloys from corrosion whose composition consists of a metal or metal alloy of the same or similar composition as the metal or metal alloy to be protected alloyed with a supersaturated concentration of usually low solubility protective elements such as refractory metals and metalloid elements.
Associated methods and systems utilized for the deposition of such coatings.

An aspect of various embodiments of the present invention may provide a number of advantages, such as but not limited thereto, the following: outperforming other coatings with less environmental harm than competing coatings.

### EXAMPLES

Practice of an aspect of an embodiment (or embodiments) of the invention will be still more fully understood from the following examples, which are presented herein for illustration only and should not be construed as limiting the invention in any way.

### Example 1

A method for protecting an aluminum substrate or an aluminum alloy substrate from corrosion, wherein the method comprises:

at least partially enclosing a substrate to be coated in an enclosure; providing a first material source comprising aluminum or aluminum alloy; providing one or more corrosion inhibiting material sources of different composition as the substrate; providing an energy source for vaporizing the first material source and the one or more corrosion inhibiting material sources; vaporizing the first material source and the one or more corrosion inhibiting material sources with the energy source to create a coating vapor; providing a gas flow for mixing and carrying the coating vapor to the substrate; and coating the sample with an alloy of the first material source and a supersaturated concentration of at least one of the one or more corrosion inhibiting material sources.

### Example 2

The method of example 1, wherein the first material source comprises the same composition as the substrate.

### Example 3

The method of example 1 (as well as subject matter of one or more of any combination of example 1), wherein the energy source comprises an electron gun.

### Example 4

The method of example 1 (as well as subject matter of one or more of any combination of examples 2-3), wherein the gas flow is high-speed gas flow.

### Example 5

The method of example 1 (as well as subject matter of one or more of any combination of examples 2-4), wherein the gas flow is supersonic.

### Example 6

The method of example 1 (as well as subject matter of one or more of any combination of examples 2-5), wherein the gas flow is through a nozzle.

### Example 7

The method of example 1 (as well as subject matter of one or more of any combination of examples 2-6), wherein the gas flow is through an annular nozzle.

### Example 8

The method of example 1 (as well as subject matter of one or more of any combination of examples 2-7), wherein the gas flow is through a nozzle concentric to the one or more corrosion inhibiting material sources.

### Example 9

The method of example 1 (as well as subject matter of one or more of any combination of examples 2-8), wherein the gas flow is configured for adequate mixing and directing of the coating vapor.

### Example 10

The method of example 1 (as well as subject matter of one or more of any combination of examples 2-9), wherein the gas flow is concentric to the one or more corrosion inhibiting material sources.

### Example 11

The method of example 1 (as well as subject matter of one or more of any combination of examples 2-10), wherein the gas flow comprises an inert gas.

### Example 12

The method of example 1 (as well as subject matter of one or more of any combination of examples 2-11), wherein the gas flow comprises helium.

### Example 13

The method of example 1 (as well as subject matter of one or more of any combination of examples 2-12), wherein the gas flow comprises a reactive gas.

### Example 14

The method of example 1 (as well as subject matter of one or more of any combination of examples 2-13), wherein the gas flow comprises nitrogen.

### Example 15

The method of example 1 (as well as subject matter of one or more of any combination of examples 2-14), further comprising:

moving the substrate relative to the gas flow and the coating vapor; or

moving both the substrate and the gas flow and the coating vapor relative to one another.

### Example 16

The method of example 1 (as well as subject matter of one or more of any combination of examples 2-15), further comprising:

moving the substrate relative to the one or more corrosion inhibiting material sources; or

moving both the substrate and the one or more corrosion inhibiting material sources relative to one another.

### Example 17

The method of example 1 (as well as subject matter of one or more of any combination of examples 2-16), further comprising:

moving the gas flow and the coating vapor relative to the substrate; or

moving both the gas flow and the coating vapor and the sample relative to one another.

### Example 18

The method of example 1, further comprising:

moving the one or more corrosion inhibiting material sources relative to the substrate; or

moving both the one or more corrosion inhibiting material sources and the substrate relative to one another.

### Example 19

The method of example 1 (as well as subject matter of one or more of any combination of examples 2-17), further comprising applying a voltage to the substrate.

### Example 20

The method of example 19 (as well as subject matter of one or more of any combination of examples 2-19), wherein the voltage is positive.

### Example 21

The method of example 19 (as well as subject matter of one or more of any combination of examples 2-20), wherein the voltage is negative.

### Example 22

The method of example 19 (as well as subject matter of one or more of any combination of examples 2-21), wherein the voltage is constant.

### Example 23

The method of example 19 (as well as subject matter of one or more of any combination of examples 2-22), wherein the voltage is alternating.

### Example 24

The method of example 1 (as well as subject matter of one or more of any combination of examples 2-23), further comprising generating a plasma to assist in coating the substrate.

### Example 25

The method of example 24 (as well as subject matter of one or more of any combination of examples 2-24), wherein the plasma is generated from an inert gas.

### Example 26

The method of example 24 (as well as subject matter of one or more of any combination of examples 2-25), wherein the plasma is generated from argon.

### Example 27

The method of example 1 (as well as subject matter of one or more of any combination of examples 2-26), further comprising generating a plasma to clean the substrate of any surface oxidation.

### Example 28

The method of example 1 (as well as subject matter of one or more of any combination of examples 2-27), wherein the substrate comprises aluminum metal.

### Example 29

The method of example 1 (as well as subject matter of one or more of any combination of examples 2-28), wherein the substrate comprises an aluminum alloy.

### Example 30

The method of example 1 (as well as subject matter of one or more of any combination of examples 2-29), wherein the one or more corrosion inhibiting materials sources comprises any one of the following: tungsten, niobium, chromium, molybdenum, tantalum, zirconium, nitrogen, boron, phosphorous, vanadium, or yttrium.

### Example 31

An apparatus for protecting an aluminum substrate or an aluminum alloy substrate from corrosion, wherein the apparatus comprises:

an enclosure; a crucible for holding at least two material sources; an energy source for vaporizing the at least two material sources; and a nozzle for directing a gas flow onto a sample resulting in a coating of a supersaturated alloy of at least one of the at least two material sources on the aluminum substrate or the aluminum alloy substrate.

### Example 32

The apparatus of example 31, wherein the energy source comprises an electron gun.

### Example 33

The apparatus of example 31 (as well as subject matter of one or more of any combination of example 32), wherein the gas flow comprises an inert gas.

### Example 34

The apparatus of example 33 (as well as subject matter of one or more of any combination of examples 32-33), wherein the inert gas comprises helium.

### Example 35

The apparatus of example 31 (as well as subject matter of one or more of any combination of examples 32-34), wherein the gas flow is a high-speed gas flow.

### Example 36

The apparatus of example 31 (as well as subject matter of one or more of any combination of examples 32-35), wherein the gas flow is supersonic.

### Example 37

The apparatus of example 31 (as well as subject matter of one or more of any combination of examples 32-36), wherein the gas flow comprises a reactive gas.

### Example 38

The apparatus of example 31, wherein the gas flow comprises nitrogen.

### Example 39

The apparatus of example 31 (as well as subject matter of one or more of any combination of examples 32-38), wherein the nozzle is annular.

### Example 40

The apparatus of example 31 (as well as subject matter of one or more of any combination of examples 32-39), wherein the nozzle is concentric to the at least two material sources.

### Example 41

The apparatus of example 31 (as well as subject matter of one or more of any combination of examples 32-40), wherein the nozzle is configured for adequate mixing and directing of the coating vapor.

### Example 42

The apparatus of example 31 (as well as subject matter of one or more of any combination of examples 32-41), wherein the gas flow is concentric to the at least two material sources.

### Example 43

The apparatus of example 31 (as well as subject matter of one or more of any combination of examples 32-42), further comprising a plasma assist comprising:

a hollow cathode; a working gas flow through the hollow cathode; and an anode disposed across the enclosure in the direction of the working gas flow.

### Example 44

The apparatus of example 43 (as well as subject matter of one or more of any combination of examples 32-43), wherein the working gas comprises an inert gas.

### Example 45

The apparatus of example 44 (as well as subject matter of one or more of any combination of examples 32-44), wherein the inert gas is argon.

### Example 46

The apparatus of example 31 (as well as subject matter of one or more of any combination of examples 32-45), wherein:

the crucible and gas flow may be moved relative to the sample; or

both the crucible and gas flow and the sample may be moved relative to one another.

### Example 47

The apparatus of example 31 (as well as subject matter of one or more of any combination of examples 32-46), wherein:

the sample may be moved relative to the crucible and the gas flow; or

both the sample and the crucible and the gas flow may be moved relative to one another.

### Example 48

A composition for coating an aluminum substrate or an aluminum alloy substrate to protect the substrate from corrosion, wherein the coating of the substrate comprises:

aluminum or aluminum alloy and one or more corrosion inhibiting materials alloyed and deposited as a coating on the aluminum or aluminum alloy substrate; wherein the alloyed and deposited coating comprises aluminum or aluminum alloy and a supersaturated concentration of at least one of the one or more corrosion inhibiting material.

### Example 49

The composition of example 48, wherein the one or more corrosion inhibiting materials comprises one or more of the following: tungsten, niobium, chromium, molybdenum, tantalum, zirconium, nitrogen, boron, phosphorous, vanadium, or yttrium.

### Example 50

The composition of example 48 (as well as subject matter of one or more of any combination of example 49), wherein the coating is substantially non-porous.

### Example 51

The composition of example 48, wherein the coating is substantially porous.

### Example 52

The composition of example 48 (as well as subject matter of one or more of any combination of examples 49-51), wherein the coating is a thin film.

### Example 53

The composition as in example 52 (as well as subject matter of one or more of any combination of examples 49-52), wherein the thin film is approximately 400 nanometers thick.

### Example 54

A method for protecting a metal substrate or a metal alloy substrate from corrosion, wherein the method comprises:

at least partially enclosing a substrate to be coated in an enclosure; providing a first material source comprising metal or metal alloy; providing one or more corrosion inhibiting material sources of different composition as the substrate; providing an energy source for vaporizing the first material source and the one or more corrosion inhibiting material sources; vaporizing the first material source and the one or more corrosion inhibiting material sources with the energy source to create a coating vapor; providing a gas flow for mixing and carrying the coating vapor to the substrate; and coating the sample with an alloy of the first material source and a supersaturated concentration of at least one of the one or more corrosion inhibiting material sources.

### Example 55

The method of example 54 (as well as subject matter of one or more of any combination of examples 2-30), wherein the first material sources comprises the same composition as the substrate.

### Example 56

The method of example 54 (as well as subject matter of one or more of any combination of examples 2-30), wherein the first material source comprising metal or metal alloy comprises any one of the following: copper, magnesium, iron, or nickel or alloys thereof.

### Example 57

The method of example 56 (as well as subject matter of one or more of any combination of examples 2-30), wherein the one or more corrosion inhibiting materials sources comprises any one of the following: tungsten, niobium, chromium, molybdenum, tantalum, zirconium, nitrogen, boron, phosphorous, vanadium, or yttrium.

### Example 58

An apparatus for protecting a metal substrate or a metal alloy substrate from corrosion, wherein the apparatus comprises:

an enclosure; a crucible for holding at least two material sources; an energy source for vaporizing the at least two material sources; and a nozzle for directing a gas flow onto a sample resulting in a coating of a supersaturated alloy of at least one of the at least two material sources on the metal substrate or the metal alloy substrate.

### Example 59

A composition for coating a metal substrate or metal alloy substrate to protect the substrate from corrosion, wherein the coating of the substrate comprises:

metal or metal alloy and one or more corrosion inhibiting materials alloyed and deposited as a coating on the metal or metal alloy substrate; wherein the alloyed and deposited coating comprises metal or metal alloy and a supersaturated concentration level of at least one of the one or more corrosion inhibiting materials.

### Example 60

The composition of example 59 (as well as subject matter of one or more of any combination of examples 2-30), wherein the metal or metal alloy comprises any one of the following: copper, magnesium, iron, or nickel or alloys thereof.

### Example 61

The composition of example 60 (as well as subject matter of one or more of any combination of examples 2-30), wherein the one or more corrosion inhibiting materials sources comprises any one of the following: tungsten, niobium, chromium, molybdenum, tantalum, zirconium, nitrogen, boron, phosphorous, vanadium, or yttrium.

### Example 62

A method for removing oxidation or contamination from a substrate, the method comprising:

providing a substrate to be cleaned or etched; generating or providing a plasma source; applying a negative bias to the substrate; and bombarding the substrate with ions of the plasma.

### Example 63

The method of example 62 (as well as subject matter of one or more of any combination of examples 2-30), further comprising coating the substrate with the method of example 1.

### Example 64

The method of example 62 (as well as subject matter of one or more of any combination of examples 2-30), further comprising coating the substrate with the method of example 54.

### Example 65

The method of example 62 (as well as subject matter of one or more of any combination of examples 2-30), further comprising coating the substrate with the apparatus of example 31.

### Example 66

The method of example 62 (as well as subject matter of one or more of any combination of examples 2-30), further comprising coating the substrate with the apparatus of example 58.

### Example 67

A method for forming a synthetic oxide layer on a substrate, the method comprising:

providing a coated or uncoated substrate to be oxidized; generating or providing a plasma source composed of a material that may oxidize the coated or uncoated substrate;

applying a negative bias to the substrate; and bombarding the substrate with the ions of the plasma.

### Example 68

The method of example 67, further comprising coating of the substrate with the method of example 1, wherein forming the synthetic oxide is carried after the coating of the substrate.

### Example 69

The method of any one of examples 1, 54, 62 or 67, wherein the substrate comprises:

a) a portion of a land, sea, air, or space vehicle, craft or robot; or

b). a portion of a building structure or building exterior.

### Example 70

The apparatus of any one of examples 31 or 58 wherein the substrate comprises:

a) a portion of a land, sea, air, or space vehicle, craft or robot; or

b). a portion of a building structure or building exterior.

### Example 71

The coating of any one of examples 48 or 59, wherein the substrate comprises:

a) a portion of a land, sea, air, or space vehicle, craft or robot; or

b). a portion of a building structure or building exterior.

### REFERENCES

The following patents, applications and publications as listed below and throughout this document are hereby incorporated by reference in their entirety herein. It should be appreciated that various aspects of embodiments of the present method, system, devices, article of manufacture, and compositions may be implemented with the following methods, systems, devices, article of manufacture, and compositions disclosed in the following U.S. patent applications, U.S. patents, Publications, and PCT International Patent Applications and are hereby incorporated by reference herein and co-owned with the assignee (and which are not admitted to be prior art with respect to the present invention by inclusion in this section):
International Patent Application Serial No. PCT/US2011/035581, entitled “Spotless Arc Directed Vapor Deposition (SA-DVD) and Related Method Thereof”, filed on May 6, 2011.
International Patent Application Serial No. PCT/US2011/031592, entitled “Multifunctional Armor Panel”, filed on Apr. 7, 2011, and corresponding U.S. application Ser. No. 13/640,239, filed on Oct. 9, 2012; U.S. Patent Application Publication No. US 2013/0263727, published Oct. 10, 2013.
International Patent Application Serial No. PCT/US2011/021121, entitled “Multifunctional Thermal Management System and Related Method”, filed Jan. 13, 2011, and corresponding U.S. patent application Ser. No. 13/522,264, entitled “Multifunctional Thermal Management System and Related Method”, filed Jul. 13, 2012; U.S. Patent Application Publication No. US 2013/0014916, published Jan. 17, 2013.
International Patent Application No. PCT/US2010/025259, entitled “Coaxial Hollow Cathode Plasma Assisted Directed Vapor Deposition and Related Method Thereof”, filed Feb. 24, 2010, and corresponding U.S. patent application Ser. No. 13/202,828, entitled “Coaxial Hollow Cathode Plasma Assisted Directed Vapor Deposition and Related Method Thereof”, filed Aug. 23, 2011; U.S. Patent Application Publication No. US 2011/0318498, published Dec. 29, 2011.
U.S. patent application Ser. No. 12/604,654, entitled “Interwoven Sandwich Panel Structures and Related Methods Thereof”, filed Oct. 23, 2009; U.S. Patent Application Publication No. US 2010/0104819, published Apr. 29, 2010.
International Patent Application No. PCT/US2009/061888 entitled “Reactive Topologically Controlled Armors for Protection and Related Method”, filed Oct. 23, 2009.
U.S. patent application Ser. No. 12/479,408, entitled “Manufacture of Lattice Truss Structures from Monolithic Materials”, filed Jun. 5, 2009; U.S. Patent Application Publication Serial No. US 2009/028610, published Nov. 19, 2009.
U.S. patent application Ser. No. 12/408,250, entitled “Cellular Lattice Structures with Multiplicity of Cell Sizes and Related Method of Use”, filed Mar. 20, 2009.
International Application No. PCT/US2009/034690, entitled “Method for Manufacture of Cellular Structure and Resulting Cellular Structure”, filed Feb. 20, 2009.
International Application No. PCT/US2008/073377, entitled “Synergistically-Layered Armor Systems and Methods for Producing Layers Thereof”, filed Aug. 15, 2008, and corresponding U.S. patent application Ser. No. 12/673,647, entitled “Synergistically-Layered Armor Systems and Methods for Producing Layers Thereof”, filed Feb. 16, 2010.
International Patent Application No. PCT/US2008/073071, entitled “Thin Film Battery Synthesis by Directed Vapor Deposition”, filed Aug. 13, 2008, and corresponding U.S. patent application Ser. No. 12/733,160, entitled “Thin Film Battery Synthesis by Directed Vapor Deposition”, filed Feb. 16, 2010.
International Patent Application No. PCT/US2008/071848, entitled “Hybrid Periodic Cellular Material Structures, Systems, and Methods for Blast and Ballistic Protection,” filed Jul. 31, 2008, and corresponding U.S. patent application Ser. No. 12/673,418, entitled “Hybrid Periodic Cellular Material Structures, Systems, and Methods for Blast and Ballistic Protection,” filed Feb. 12, 2010; U.S. Patent Application Publication No. US 2011/0283873, published Nov. 24, 2011.
International Application No. PCT/US2008/060637, entitled “Heat-Managing Composite Structures,” filed Apr. 17, 2008, and corresponding U.S. patent application Ser. No. 12/596,548, entitled “Heat-Managing Composite Structures”, filed Oct. 19, 2009; U.S. Patent Application Publication No. US 2010/0236759, published Sep. 23, 2010.
International Application No. PCT/US2007/022733, entitled “Manufacture of Lattice Truss Structures from Monolithic Materials,” filed Oct. 26, 2007, and corresponding U.S. patent application Ser. No. 12/447,166, entitled “Manufacture of Lattice Truss Structures from Monolithic Materials,” filed Apr. 24, 2009; U.S. Pat. No. 8,176,635, issued May 15, 2012, and corresponding U.S. patent application Ser. No. 13/448,074, entitled “Manufacture of Lattice Truss Structures from Monolithic Materials,” filed Apr. 16, 2012.
International Application No. PCT/US2007/012268, entitled “Method and Apparatus for Jet Blast Deflection,” filed May 23, 2007, and corresponding U.S. patent application Ser. No. 12/301,916, entitled “Method and Apparatus for Jet Blast Deflection,” filed Oct. 7, 2009; U.S. Pat. No. 8,360,361, issued Jan. 29, 2013.
International Patent Application No. PCT/US2006/025978, entitled “Reliant Thermal Barrier Coating System and Related Methods and Apparatus of Making the Same,” filed Jun. 30, 2006, and corresponding U.S. patent application Ser. No. 11/917,585, entitled “Reliant Thermal Barrier Coating System and Related Methods and Apparatus of Making the Same,” filed Dec. 14, 2007; U.S. Pat. No. 8,084,086 issued Dec. 27, 2011, and corresponding U.S. patent application Ser. No. 13/337,133, entitled “Reliant Thermal Barrier Coating System and Related Methods and Apparatus of Making the Same,” filed Dec. 25, 2011; U.S. Patent Application Publication No. 2012/0160166, published Jun. 28, 2012.
International Patent Application No. PCT/US2005/000606, entitled “Apparatus and Method for Applying Coatings onto the Interior Surfaces of Components and Related Structures Produced Therefrom,” filed Jan. 10, 2005, and corresponding U.S. patent application Ser. No. 10/584,682, entitled “Apparatus and Method for Applying Coatings onto the Interior Surfaces of Components and Related Structures Produced Therefrom,” filed Jun. 28, 2006; U.S. Pat. No. 8,110,143, issued Feb. 7, 2012.
International Patent Application No. PCT/US2004/024232, entitled “Method for Application of a Thermal Barrier Coating and Resultant Structure Thereof,” filed Jul. 28, 2004, and corresponding U.S. patent application Ser. No. 10/566,316, entitled “Method for Application of a Thermal Barrier Coating and Resultant Structure Thereof,” filed Jan. 27, 2006.
International Application No. PCT/US04/04608, entitled “Methods for Manufacture of Multilayered Multifunctional Truss Structures and Related Structures There from,” filed Feb. 17, 2004, and corresponding U.S. patent application Ser. No. 10/545,042, entitled “Methods for Manufacture of Multilayered Multifunctional Truss Structures and Related Structures There from,” filed Aug. 11, 2005.
International Patent Application No. PCT/US2003/037485, entitled “Bond Coat for a Thermal Barrier Coating System and Related Method Thereof,” filed Nov. 21, 2003, corresponding to U.S. patent application Ser. No. 10/535,364, entitled “Bond Coat for a Thermal Barrier Coating System and Related Method Thereof,” filed May 18, 2005.
International Patent Application No. PCT/US2003/036035, entitled “Extremely Strain Tolerant Thermal Protection Coating and Related Method and Apparatus Thereof,” filed Nov. 12, 2003, and corresponding to U.S. patent application Ser. No. 10/533,993, entitled “Extremely Strain Tolerant Thermal Protection Coating and Related Method and Apparatus Thereof,” filed May 5, 2005.
International Application No. PCT/US03/27606, entitled “Method for Manufacture of Truss Core Sandwich Structures and Related Structures Thereof,” filed Sep. 3, 2003, and corresponding U.S. patent application Ser. No. 10/526,296, entitled “Method for Manufacture of Truss Core Sandwich Structures and Related Structures Thereof,” filed Mar. 1, 2005; U.S. Pat. No. 7,424,967, issued Sep. 16, 2008.
International Patent Application Serial No. PCT/US03/27605, entitled “Blast and Ballistic Protection Systems and Methods of Making Same,” filed Sep. 3, 2003, and corresponding U.S. patent application Ser. No. 10/526,414, entitled “Blast and Ballistic Protection Systems and Methods of Making Same,” filed Mar. 2, 2005; U.S. Pat. No. 7,913,611, issued Mar. 29, 2011.
International Patent Application No. PCT/US2003/023111, entitled “Method and Apparatus for Dispersion Strengthened Bond Coats for Thermal Barrier Coatings,” filed Jul. 24, 2003, and corresponding U.S. patent application Ser. No. 10/522,076, entitled “Method and Apparatus for Dispersion Strengthened Bond Coats for Thermal Barrier Coatings,” filed Jan. 21, 2005.
International Patent Application Serial No. PCT/US03/23043, entitled “Method for Manufacture of Cellular Materials and Structures for Blast and Impact Mitigation and Resulting Structure,” filed Jul. 23, 2003, and corresponding U.S. patent application Ser. No. 10/522,067, entitled “Method for Manufacture of Cellular Materials and Structures for Blast and Impact Mitigation and Resulting Structure,” filed Jan. 21, 2005.
International Patent Application No. PCT/US2003/017049, entitled “Active Energy Absorbing Cellular Metals and Method of Manufacturing and Using the Same,” filed May 30, 2003, and corresponding U.S. patent application Ser. No. 10/516,052 entitled “Active Energy Absorbing Cellular Metals and Method of Manufacturing and Using the Same,” filed Nov. 29, 2004; U.S. Pat. No. 7,288,326, issued Oct. 30, 2007, and corresponding U.S. patent application Ser. No. 11/857,856, entitled “Active Energy Absorbing Cellular Metals and Method of Manufacturing and Using the Same,” filed Sep. 19, 2007.
International Application No. PCT/US03/16844, entitled “Method for Manufacture of Periodic Cellular Structure and Resulting Periodic Cellular Structure,” filed May 29, 2003, and corresponding U.S. patent application Ser. No. 10/515,572, entitled “Method for Manufacture of Periodic Cellular Structure and Resulting Periodic Cellular Structure,” filed Nov. 23, 2004.
International Patent Application No. PCT/US2003/012920, entitled “Apparatus and Method for Uniform Line of Sight and Non-Line of Sight Coating at High Rate,” filed Apr. 25, 2003, and corresponding U.S. patent application Ser. No. 10/512,161, entitled “Apparatus and Method for Uniform Line of Sight and Non-Line of Sight Coating at High Rate,” filed Oct. 15, 2004; U.S. Pat. No. 7,718,222, issued May 18, 2010.
U.S. patent application Ser. No. 10/246,018, entitled “Apparatus and Method for Intra-layer Modulation of the Material Deposition and Assist Beam and the Multilayer Structure Produced Therefrom,” filed Sep. 18, 2002, and corresponding U.S. patent application Ser. No. 09/634,457, entitled “Apparatus and Method for Intra-Layer Modulation of the Material Deposition and Assist Beam and the Multilayer Structure Produced Therefrom,” filed Aug. 7, 2000; U.S. Pat. No. 6,478,931, issued Nov. 12, 2002.
International Patent Application No. PCT/US2002/28654, entitled “Method and Apparatus for Application of Metallic Alloy Coatings,” filed Sep. 10, 2002, and corresponding to U.S. patent application Ser. No. 10/489,090, entitled “Method and Apparatus Application of Metallic Alloy Coatings,” filed Mar. 9, 2004; U.S. Pat. No. 8,124,178, issued Feb. 28, 2012, and corresponding U.S. patent application Ser. No. 13/371,044, entitled “Method and Apparatus Application of Metallic Alloy Coatings,” filed Feb. 10, 2012; U.S. Patent Application Publication No. US 2012/0137974, published Jun. 7, 2012.
International Patent Application No. PCT/US2002/27116, entitled “Reversible Shape Memory Multifunctional Structural Designs and Method of Using and Making the Same,” filed Aug. 26, 2002, and corresponding U.S. patent application Ser. No. 10/487,291, entitled “Reversible Shape Memory Multifunctional Structural Designs and Method of Using and Making the Same,” filed Feb. 20, 2004; U.S. Pat. No. 7,669,799, issued Mar. 2, 2010.
International Application No. PCT/US02/17942, entitled “Multifunctional Periodic Cellular Solids and the Method of Making Thereof,” filed Jun. 6, 2002, and corresponding U.S. patent application Ser. No. 10/479,833, entitled “Multifunctional Periodic Cellular Solids and the Method of Making Thereof,” filed Dec. 5, 2003; U.S. Pat. No. 7,963,085, issued Jun. 21, 2011, and corresponding U.S. patent application Ser. No. 13/164,189, entitled “Multifunctional Periodic Cellular Solids and the Method of Making the Same,” filed Jun. 20, 2011.
International Patent Application No. PCT/US2002/13639, entitled “Method and Apparatus for Efficient Application of Substrate Coating,” filed Apr. 30, 2002, and corresponding U.S. patent application Ser. No. 10/476,309, entitled “Method and Apparatus for Efficient Application of Substrate Coating,” filed Oct. 29, 2003; U.S. Pat. No. 7,879,411, issued Feb. 1, 2011.
International Application No. PCT/US01/25158, entitled “Multifunctional Battery and Method of Making the Same,” filed Aug. 10, 2001, and corresponding U.S. patent application Ser. No. 10/110,368, entitled “Multifunctional Battery and Method of Making the Same,” filed Apr. 9, 2002; U.S. Pat. No. 7,211,348, issued May 1, 2007, and corresponding U.S. patent application Ser. No. 11/788,958, entitled “Multifunctional Battery and Method of Making the Same,” filed Apr. 23, 2007; U.S. Patent Application Publication No. 2007/0269716, published Nov. 22, 2007.
International Application No. PCT/US01/22266, entitled “Method and Apparatus For Heat Exchange Using Hollow Foams and Interconnected Networks and Method of Making the Same,” filed Jul. 16, 2001, and corresponding U.S. patent application Ser. No. 10/333,004, entitled “Heat Exchange Foam,” filed Jan. 14, 2003; U.S. Pat. No. 7,401,643 issued Jul. 22, 2008, and corresponding U.S. patent application Ser. No. 11/928,161, “Method and Apparatus For Heat Exchange Using Hollow Foams and Interconnected Networks and Method of Making the Same,” filed Oct. 30, 2007.
International Application No. PCT/US01/17363, entitled “Multifunctional Periodic Cellular Solids and the Method of Making Thereof,” filed May 29, 2001, and corresponding U.S. patent application Ser. No. 10/296,728, entitled “Multifunctional Periodic Cellular Solids and the Method of Making Thereof,” filed Nov. 25, 2002; U.S. Pat. No. 8,247,333, issued Aug. 21, 2012.
International Patent Application No. PCT/US2001/16693, entitled “A Process and Apparatus for Plasma Activated Deposition in Vacuum,” filed May 23, 2001, and corresponding U.S. patent application Ser. No. 10/297,347, entitled “Process and Apparatus for Plasma Activated Deposition in a Vacuum,” filed Nov. 21, 2002; U.S. Pat. No. 7,014,889, issued Mar. 21, 2006.
International Patent Application No. PCT/US1999/13450, entitled “Apparatus and Method for Producing Thermal Barrier Coatings,” filed Jun. 15, 1999.
International Patent Application No. PCT/US1997/11185, entitled “Production Of Nanometer Particles By Directed Vapor Deposition of Electron Beam Evaporant,” filed Jul. 8, 1997.
U.S. patent application Ser. No. 08/679,435, entitled “Production of Nanometer Particles by Directed Vapor Deposition of Electron Beam Evaporant,” filed Jul. 8, 1996; U.S. Pat. No. 5,736,073, issued Apr. 7, 1998.
U.S. patent application Ser. No. 08/298,614, entitled “Directed Vapor Deposition of Electron Beam Evaporant,” filed Aug. 31, 1994; U.S. Pat. No. 5,534,314, issued Jul. 9, 1996.
U.S. Pat. No. 3,562,131, Morley, J., “Vacuum Vapor Deposition Utilizing Low Voltage Electron Beam”, Feb. 9, 1971.
U.S. Pat. No. 5,256,205, Schmitt, III, et al., “Microwave Plasma Assisted Supersonic Gas Jet Deposition of Thin Film Materials”, Oct. 26, 1993.
U.S. Pat. No. 5,960,835, Isaki, et al., “Cast Iron Pipe Surface-Modified for Corrosion Prevention and Method of Modifying the Cast Iron Pipe Surface for Corrosion Prevention”, Oct. 5, 1999.
U.S. Patent Application Publication No. US 2013/0202815 A1, Hass, et al., “Method for Applying Aluminum Alloy Coatings for Corrosion Protection of Steel”, Aug. 8, 2013.
U.S. Patent Application Publication No. US 2014/0014038 A1, Shin, et al., “Plasma Enhanced Chemical Vapor Deposition Apparatus and Method for Controlling the Same”, Jan. 16, 2014.
International Patent Application Publication No. WO 2007/089216 A1, Gorokhovsky, V., “Plasma Vapor Deposition Method and Apparatus Utilizing Bipolar Bias Controller”, Aug. 9, 2007.
U.S. Pat. No. 5,494,704, Ackerman, J., “Low Temperature Chemical Vapor Deposition of Protective Coating Containing Platinum”, Feb. 27, 1996.
U.S. Pat. No. 5,135,817, Shimogori, et al., “ZN-MG Alloy Vapor Deposition Plated Metals of High Corrosion Resistance, as well as Method of Producing Them”, Aug. 4, 1992.
Natishan, P. M., McCafferty, E. and Hubler, G. K., Journal of the Electrochemical Society, 1986. 133: p. 1061.
Natishan, P. M., McCafferty, E. and Hubler, G. K., H. Electrochem. Soc., 1988. 135: p. 321
McCafferty, E., Natishan, P. M., and Hubler, G. K., Nucl. Instrum. Methods Phys. Res., 1991. B56/57: p. 639
McCafferty, E., Natishan, P. M., and Hubler, G. K., Corros. Sci., 1993. 35: p. 239
Moshier, W. C., Davis, G. D., Ahearn J. S. and Hough, H. F., J. Electrochem. Soc., 1986. 133: p. 1063
Shaw, B. L., Fritz, T. L., Davis, G. D., and Moshier, W. C., J. Electrochem. Soc., 1990. 137: p. 1317
Frankel, G. S., Russak, M. A., Jahnes, C. V., Mirzamaani, M., and Brusic, V. A., J. Electrochem. Soc., 1989. 136: p. 1243
Groves, J. F. and Wadley, H. N. G. Composites Part B: Engineering, 1997. 28(1-2): p. 57
Kim, Y. G. and Wadley, H. N. G., Journal of Power Sources, 2009. 187(2): p. 591
Yu, Z., Hass, D. D. and Wadley, H. N. G. Materials Science and Engineering A, 2005. 394(1-2): p. 43
Groves, J. F., Directed Vapor Deposition, PhD Thesis, Department of Materials Science and Engineering, 1998, University of Virginia: Charlottesville, Va.
Morgner, H., et al., Surface and Coatings Technology, 1998. 108-109(0): p. 513.
Schiller, S., C. Metzner, and. Zywitzki, O Surface and Coatings Technology, 2000. 125(1-3): p. 240.
Zywitzki, O., K. Goedicke, and. Morgner, H Surface and Coatings Technology, 2002. 151-152(0): p. 14.
Bunshah, R. F., Handbook of Deposition Technologies for Films and Coatings—Science, Technology and Applications (2nd Edition), 1994, William Andrew Publishing/Noyes.
Mattox, D. M., Fundamentals of Ion Plating. Vol. 10. 1973: AVS. 47-52.
Mattox, D. M. and G. J. Kominiak, Structure Modification by Ion Bombardment during Deposition. Vol. 9. 1972: AVS. 528-532.

In summary, while the present invention has been described with respect to specific embodiments, many modifications, variations, alterations, substitutions, and equivalents will be apparent to those skilled in the art. The present invention is not to be limited in scope by the specific embodiment described herein. Indeed, various modifications of the present invention, in addition to those described herein, will be apparent to those of skill in the art from the foregoing description and accompanying drawings. Accordingly, the invention is to be considered as limited only by the spirit and scope of the following claims, including all modifications and equivalents.

Still other embodiments will become readily apparent to those skilled in this art from reading the above-recited detailed description and drawings of certain exemplary embodiments. It should be understood that numerous variations, modifications, and additional embodiments are possible, and accordingly, all such variations, modifications, and embodiments are to be regarded as being within the spirit and scope of this application. For example, regardless of the content of any portion (e.g., title, field, background, summary, abstract, drawing figure, etc.) of this application, unless clearly specified to the contrary, there is no requirement for the inclusion in any claim herein or of any application claiming priority hereto of any particular described or illustrated activity or element, any particular sequence of such activities, or any particular interrelationship of such elements. Moreover, any activity can be repeated, any activity can be performed by multiple entities, and/or any element can be duplicated. Further, any activity or element can be excluded, the sequence of activities can vary, and/or the interrelationship of elements can vary. Unless clearly specified to the contrary, there is no requirement for any particular described or illustrated activity or element, any particular sequence or such activities, any particular size, speed, material, dimension or frequency, or any particular interrelationship of such elements. Accordingly, the descriptions and drawings are to be regarded as illustrative in nature, and not as restrictive. Moreover, when any number or range is described herein, unless clearly stated otherwise, that number or range is approximate. When any range is described herein, unless clearly stated otherwise, that range includes all values therein and all sub ranges therein. Any information in any material (e.g., a United States/foreign patent, United States/foreign patent application, book, article, etc.) that has been incorporated by reference herein, is only incorporated by reference to the extent that no conflict exists between such information and the other statements and drawings set forth herein. In the event of such conflict, including a conflict that would render invalid any claim herein or seeking priority hereto, then any such conflicting information in such incorporated by reference material is specifically not incorporated by reference herein.

1. A method for protecting an aluminum substrate or an aluminum alloy substrate from corrosion, wherein said method comprises:
at least partially enclosing a substrate to be coated in an enclosure;
providing a first material source comprising aluminum or aluminum alloy;
providing one or more corrosion inhibiting material sources of different composition as said substrate;
providing an energy source for vaporizing said first material source and said one or more corrosion inhibiting material sources;
vaporizing said first material source and said one or more corrosion inhibiting material sources with said energy source to create a coating vapor;
providing a gas flow for mixing and carrying said coating vapor to said substrate; and
coating said sample with an alloy of said first material source and a supersaturated concentration of at least one of said one or more corrosion inhibiting material sources.

2. The method of claim 1, wherein said first material source comprises the same composition as said substrate.

3. The method of claim 1, wherein said energy source comprises an electron gun.

4. The method of claim 1, wherein said gas flow is high-speed gas flow.

5. The method of claim 1, wherein said gas flow is supersonic.

6. The method of claim 1, wherein said gas flow is through a nozzle.

7. The method of claim 1, wherein said gas flow is through an annular nozzle.

8. The method of claim 1, wherein said gas flow is through a nozzle concentric to said one or more corrosion inhibiting material sources.

9. The method of claim 1, wherein said gas flow is configured for adequate mixing and directing of said coating vapor.

10. The method of claim 1, wherein said gas flow is concentric to said one or more corrosion inhibiting material sources.

11. The method of claim 1, wherein said gas flow comprises an inert gas.

12. The method of claim 1, wherein said gas flow comprises helium.

13. The method of claim 1, wherein said gas flow comprises a reactive gas.

14. The method of claim 1, wherein said gas flow comprises nitrogen.

15. The method of claim 1, further comprising:
moving said substrate relative to said gas flow and said coating vapor; or
moving both said substrate and said gas flow and said coating vapor relative to one another.

16. The method of claim 1, further comprising:
moving said substrate relative to said one or more corrosion inhibiting material sources, or
moving both said substrate and said one or more corrosion inhibiting material sources relative to one another.

17. The method of claim 1, further comprising:
moving said gas flow and said coating vapor relative to said substrate; or
moving both said gas flow and said coating vapor and said sample relative to one another.

18. The method of claim 1, further comprising:
moving said one or more corrosion inhibiting material sources relative to said substrate; or
moving both said one or more corrosion inhibiting material sources and said substrate relative to one another.

19. The method of claim 1, further comprising applying a voltage to said substrate.

20. The method of claim 19, wherein said voltage is positive.

21. The method of claim 19, wherein said voltage is negative.

22. The method of claim 19, wherein said voltage is constant.

23. The method of claim 19, wherein said voltage is alternating.

24. The method of claim 1, further comprising generating a plasma to assist in coating said substrate.

25. The method of claim 24, wherein said plasma is generated from an inert gas.

26. The method of claim 24, wherein said plasma is generated from argon.

27. The method of claim 1, further comprising generating a plasma to clean said substrate of any surface oxidation.

28. The method of claim 1, wherein said substrate comprises aluminum metal.

29. The method of claim 1, wherein said substrate comprises an aluminum alloy.

30. The method of claim 1, wherein said one or more corrosion inhibiting materials sources comprises any one of the following: tungsten, niobium, chromium, molybdenum, tantalum, zirconium, nitrogen, boron, phosphorous, vanadium, or yttrium.

31-47. (canceled)

48. A composition for coating an aluminum substrate or an aluminum alloy substrate to protect the substrate from corrosion, wherein said coating of said substrate comprises:
aluminum or aluminum alloy and one or more corrosion inhibiting materials alloyed and deposited as a coating on the aluminum or aluminum alloy substrate; wherein said alloyed and deposited coating comprises aluminum or aluminum alloy and a supersaturated concentration of at least one of said one or more corrosion inhibiting material.

49. The composition of claim 48, wherein said one or more corrosion inhibiting materials comprises one or more of the following: tungsten, niobium, chromium, molybdenum, tantalum, zirconium, nitrogen, boron, phosphorous, vanadium, or yttrium.

50. The composition of claim 48, wherein said coating is substantially non-porous.

51. The composition of claim 48, wherein said coating is substantially porous.

52. The composition of claim 48, wherein said coating is a thin film.

53. The composition as in claim 52, wherein said thin film is approximately 400 nanometers thick.

54. A method for protecting a metal substrate or a metal alloy substrate from corrosion, wherein said method comprises:
at least partially enclosing a substrate to be coated in an enclosure;
providing a first material source comprising metal or metal alloy;
providing one or more corrosion inhibiting material sources of different composition as said substrate;
providing an energy source for vaporizing said first material source and said one or more corrosion inhibiting material sources;
vaporizing said first material source and said one or more corrosion inhibiting material sources with said energy source to create a coating vapor;
providing a gas flow for mixing and carrying said coating vapor to said substrate; and coating said sample with an alloy of said first material source and a supersaturated concentration of at least one of said one or more corrosion inhibiting material sources.

55. The method of claim 54, wherein said first material sources comprises the same composition as said substrate.

56. The method of claim 54, wherein said first material source comprising metal or metal alloy comprises any one of the following: copper, magnesium, iron, or nickel or alloys thereof.

57. The method of claim 56, wherein said one or more corrosion inhibiting materials sources comprises any one of the following: tungsten, niobium, chromium, molybdenum, tantalum, zirconium, nitrogen, boron, phosphorous, vanadium, or yttrium.

58. An apparatus for protecting a metal substrate or a metal alloy substrate from corrosion, wherein said apparatus comprises:
an enclosure;
a crucible for holding at least two material sources;
an energy source for vaporizing said at least two material sources; and
a nozzle for directing a gas flow onto a sample resulting in a coating of a supersaturated alloy of at least one of said at least two material sources on said metal substrate or said metal alloy substrate.

59. A composition for coating a metal substrate or metal alloy substrate to protect the substrate from corrosion, wherein said coating of said substrate comprises:
metal or metal alloy and one or more corrosion inhibiting materials alloyed and deposited as a coating on the metal or metal alloy substrate; wherein said alloyed and deposited coating comprises metal or metal alloy and a supersaturated concentration level of at least one of said one or more corrosion inhibiting materials.

60. The composition of claim 59, wherein said metal or metal alloy comprises any one of the following: copper, magnesium, iron, or nickel or alloys thereof.

61. The composition of claim 60, wherein said one or more corrosion inhibiting materials sources comprises any one of the following: tungsten, niobium, chromium, molybdenum, tantalum, zirconium, nitrogen, boron, phosphorous, vanadium, or yttrium.

62. A method for removing oxidation or contamination from a substrate, said method comprising:
providing a substrate to be cleaned or etched;
generating or providing a plasma source;
applying a negative bias to said substrate; and
bombarding said substrate with ions of said plasma.

63. The method of claim 62, further comprising coating said substrate with the method of claim 1.

64. The method of claim 62, further comprising coating said substrate with the method of claim 54.

65. The method of claim 62, further comprising coating said substrate with the apparatus of claim 31.

66. The method of claim 62, further comprising coating said substrate with the apparatus of claim 58.

67. A method for forming a synthetic oxide layer on a substrate, said method comprising:
providing a coated or uncoated substrate to be oxidized;
generating or providing a plasma source composed of a material that may oxidize said coated or uncoated substrate;
applying a negative bias to said substrate; and
bombarding said substrate with said ions of said plasma.

68. The method of claim 67, further comprising coating of said substrate with the method of claim 1, wherein forming the synthetic oxide is carried after said coating of said substrate.

69. The method of any one of claims 1, 54, 62 or 67, wherein said substrate comprises:
a) a portion of a land, sea, air, or space vehicle, craft or robot; or
b) a portion of a building structure or building exterior.

70. The apparatus of any one of claims 31 or 58 wherein said substrate comprises:
a) a portion of a land, sea, air, or space vehicle, craft or robot; or
b) a portion of a building structure or building exterior.

71. The coating of any one of claims 48 or 59, wherein said substrate comprises:
a) a portion of a land, sea, air, or space vehicle, craft or robot; or
b) a portion of a building structure or building exterior.
